(19) United States
(12) Patent Application Publication
(10) Pub. No.: US 2026/0090380 A1
(43) Pub. Date: Mar. 26, 2026

(54) SEMICONDUCTOR PACKAGE

(71) Applicant: SAMSUNG ELECTRONICS CO., LTD., Suwon-si (KR)

(72) Inventors: MINJUNG KIM, Suwon-si (KR); ILHO KIM, Suwon-si (KR)

(73) Assignee: SAMSUNG ELECTRONICS CO., LTD., Suwon-si (KR)

(21) Appl. No.: 19/335,281

(22) Filed: Sep. 22, 2025

(30) Foreign Application Priority Data
Sep. 23, 2024 (KR) 10-2024-0128512

(51) Int. Cl. H01L 23/373; H01L 21/56; H01L 23/00; H01L 23/31; H01L 23/433; H01L 23/498; H01L 23/538; H01L 25/065; H01L 25/10; H01L 25/18; H10B 80/00; H10D 80/30

(52) U.S. Cl. CPC H10W 40/251; H10W 40/778; H10W 70/611; H10W 70/685; H10W 70/69; H10W 74/016; H10W 74/121; H10W 90/00; H10B 80/00; H10D 80/30; H10W 72/07207; H10W 72/07253; H10W 72/07307; H10W 72/234; H10W 90/724; H10W 90/733; H10W 90/736

(57) ABSTRACT

A semiconductor package may include: a first wiring structure including a first wiring pattern and a first wiring insulating layer surrounding the first wiring pattern; a first semiconductor chip above the first wiring structure; a second semiconductor chip above the first wiring structure and spaced apart from the first semiconductor chip in a horizontal direction; an adhesive layer including a first portion on an upper surface of the first semiconductor chip, and further including a second portion on an upper surface of the second semiconductor chip; a molding member on the first wiring structure and surrounding side surfaces of each of the first semiconductor chip, the second semiconductor chip, and the adhesive layer; and a heat dissipation member on an upper surface of each of the molding member and the adhesive layer.

### CROSS-REFERENCE TO RELATED APPLICATION

This application is based on and claims priority under 35 U.S. C. § 119 to Korean Patent Application No. 10-2024-0128512, filed on Sep. 23, 2024, in the Korean Intellectual Property Office, the disclosure of which is incorporated by reference herein in its entirety.

### BACKGROUND

Some embodiments of the present disclosure are directed to a semiconductor package, and more particularly, to a semiconductor package including a heat dissipation member.

In recent years, the electronics market has seen a dramatic increase in the demand for portable devices, which has led to an ongoing need to reduce the size and weight of electronic components in the electronics. In order to reduce the size and weight of the electronic components, semiconductor packages mounted on the electronic components are becoming smaller and smaller in volume. However, these semiconductor packages are still required to process large amounts of data. As the semiconductor packages decrease in size and weight, dissipation of heat from the semiconductor packages has to be addressed.

### SUMMARY

According to embodiments of the present disclosure, a semiconductor package with improved thermal characteristics may be provided.

According to embodiments of the present disclosure, a semiconductor package may be provided and include: a first wiring structure including a first wiring pattern and a first wiring insulating layer surrounding the first wiring pattern; a first semiconductor chip above the first wiring structure; a second semiconductor chip above the first wiring structure and spaced apart from the first semiconductor chip in a horizontal direction; an adhesive layer including a first portion on an upper surface of the first semiconductor chip, and further including a second portion on an upper surface of the second semiconductor chip; a molding member on the first wiring structure and surrounding side surfaces of each of the first semiconductor chip, the second semiconductor chip, and the adhesive layer; and a heat dissipation member on an upper surface of each of the molding member and the adhesive layer.

According to embodiments of the present disclosure, a semiconductor package may be provided and include: a first wiring structure including a first wiring pattern and a first wiring insulating layer surrounding the first wiring pattern; a first semiconductor chip above the first wiring structure; a second semiconductor chip above the first wiring structure and spaced apart from the first semiconductor chip in a horizontal direction; a heat dissipation member above the first semiconductor chip and the second semiconductor chip; a molding film bonding the heat dissipation member to the first semiconductor chip and the second semiconductor chip; and a molding member on the first wiring structure and surrounding side surfaces of each of the first semiconductor chip and the second semiconductor chip, wherein a thermal conductivity of the molding film is greater than a thermal conductivity of the molding member.

According to embodiments of the present disclosure, a semiconductor package may be provided and include: a first wiring structure including a first wire and a first wiring insulating layer surrounding the first wire; a first semiconductor chip above the first wiring structure and connected to the first wiring structure via a first chip connection bump; a second semiconductor chip above the first wiring structure and connected to the first wiring structure via a second chip connection bump, the second semiconductor chip spaced apart from the first semiconductor chip in a horizontal direction; a dummy block on the first wiring structure and spaced apart from each of the first semiconductor chip and the second semiconductor chip in the horizontal direction; an adhesive layer including a first portion on an upper surface of the first semiconductor chip, and further including a second portion on an upper surface of the second semiconductor chip; a molding member on the first wiring structure and surrounding side surfaces of each of the first semiconductor chip, the second semiconductor chip, the dummy block, and the adhesive layer; and a heat dissipation member on an upper surface of each of the molding member, the dummy block, and the adhesive layer, wherein the molding member is between the first semiconductor chip and the first wiring structure and between the second semiconductor chip and the first wiring structure, and the molding member surrounds the first chip connection bump and the second chip connection bump, wherein a surface of the first chip connection bump, that faces away from the first semiconductor chip, and a surface the second chip connection bump, that faces away from the second semiconductor chip, are flat, and wherein the upper surface of the adhesive layer is coplanar with the upper surface of the molding member.

Aspects and effects of embodiments of the present disclosure are not limited to the aforementioned aspects and effects, and other aspects and effects of embodiments of the present disclosure not described herein will be clearly understood by those skilled in the art from the following description.

### BRIEF DESCRIPTION OF DRAWINGS

Embodiments will be more clearly understood from the following detailed description taken in conjunction with the accompanying drawings in which:

FIG. 1 is a cross-sectional view showing a semiconductor package according to an embodiment;

FIG. 2 is a cross-sectional view showing a semiconductor package according to an embodiment;

FIG. 3 is a cross-sectional view showing one example of the semiconductor package taken along a line A1-A1′ of FIG. 2;

FIG. 4 is a cross-sectional view showing one example of the semiconductor package taken along the line A1-A1′ of FIG. 2;

FIG. 5 is a cross-sectional view showing a semiconductor package according to an embodiment;

FIG. 6 is a cross-sectional view showing a semiconductor package according to an embodiment;

FIG. 7 is a cross-sectional view showing a semiconductor package according to an embodiment;

FIGS. 8 to 13 are cross-sectional views illustrating a method of manufacturing the semiconductor package of FIG. 1;

FIGS. 14 to 19 are cross-sectional views illustrating a method of manufacturing the semiconductor package of FIG. 2;

FIGS. 20 to 25 are cross-sectional views illustrating a method of manufacturing the semiconductor package of FIG. 5; and

FIGS. 26 to 31 are cross-sectional views illustrating a method of manufacturing the semiconductor package of FIG. 6.

### DETAILED DESCRIPTION

Hereinafter, non-limiting embodiments of the present disclosure are described in detail with reference to the accompanying drawings. The same reference numerals are given to the same elements in the drawings, and repeated descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

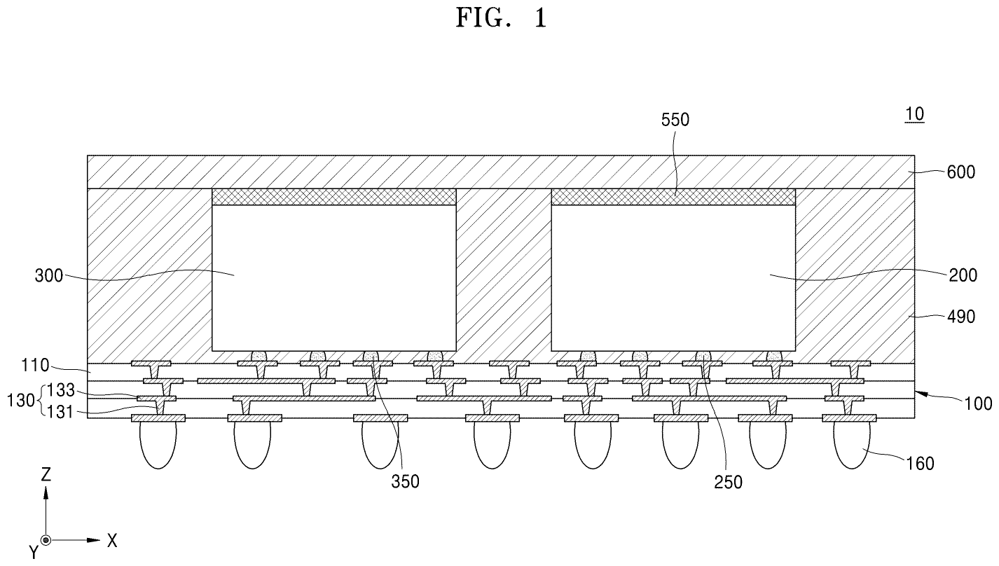

FIG. 1 is a cross-sectional view showing a semiconductor package 10 according to an embodiment.

Referring to FIG. 1, the semiconductor package 10 according to an embodiment of the present disclosure may include a first wiring structure 100, a first semiconductor chip 200, a second semiconductor chip 300, an adhesive layer 550, and a heat dissipation member 600.

The first wiring structure 100 may include an upper surface and a lower surface that are opposite to each other, and at least one from among the upper surface and the lower surface of the first wiring structure 100 may be planar. The first wiring structure 100 may be disposed below the first semiconductor chip 200 and the second semiconductor chip 300, and may electrically connect the first semiconductor chip 200 to at least one external connection bump 160 and electrically connect the second semiconductor chip 300 to the at least one external connection bump 160.

The first wiring structure 100 may include a first wiring insulating layer 110 and a first wiring pattern 130. The first wiring insulating layer 110 may be provided as a plurality of insulating layers stacked in one direction, and the first wiring pattern 130 may include a plurality of patterns formed inside the stacked insulating layers.

In the drawings, the direction in which the plurality of insulating layers are stacked may be understood as a Z-axis direction, and an X-axis direction and a Y-axis direction may be understood as directions perpendicular to each other in a plane having the Z-axis direction as a normal vector. Similarly, the X-axis direction and the Y-axis direction may represent directions parallel to the upper surface or the lower surface of the first wiring structure 100, and the X-axis direction and the Y-axis direction may be perpendicular to each other. Also, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first wiring pattern 130 may be electrically connected to the first semiconductor chip 200 and the second semiconductor chip 300. The first wiring pattern 130 may include a first wiring via 131 and a first wiring line 133. The first wiring line 133 may have a shape extending in the first horizontal direction X inside the first wiring insulating layer 110. According to embodiments, the first wiring line 133 may be provided in each of a plurality of first wiring insulating layers 110 that are stacked in the vertical direction Z. The first wiring via 131 may extend in the vertical direction Z and pass through the first wiring insulating layer 110 in the vertical direction Z. The first wiring via 131 may electrically connect a plurality of the first wiring lines 133 to each other, which may be respectively formed in different ones of the first wiring insulating layers 110.

In some embodiments, the first wiring via 131 may have a tapered shape extending from a bottom to a top of the first wiring via 131 with an increasing horizontal width. For example, the first wiring via 131 may increase in horizontal width toward the first semiconductor chip 200. In some embodiments, the first wiring via 131 may have a tapered shape with a horizontal width that increases as the level in the vertical direction Z decreases.

In some embodiments, the first wiring structure 100 may include a redistribution structure manufactured through a redistribution process. For example, the first wiring structure 100 may be formed by a semi-additive process (SAP), a dual damascene process, a tenting process, or the like. In this case, the first wiring insulating layer 110 may include, for example, photo imageable dielectric (PID) or photosensitive polyimide (PSPI). For example, the first wiring pattern 130 may include, but is not limited to, metals or alloys of the metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru). In some embodiments, the first wiring pattern 130 may be formed by stacking metals or alloys of the metals on a seed layer including copper, titanium, titanium nitride, or titanium tungsten. According to embodiments, the first wiring line 133 may be formed together with the first wiring via 131 to form a single body.

When the first wiring structure 100 includes the redistribution structure manufactured through the redistribution process as described above, the first wiring pattern 130 may be understood as a redistribution pattern and the first wiring insulating layer 110 may be understood as a redistribution insulating layer.

In some embodiments, the first wiring structure 100 may include a printed circuit board (PCB). In this case, the first wiring insulating layer 110 may include at least one material selected from among phenolic resin, epoxy resin, and polyimide. The first wiring insulating layer 110 may include, for example, at least one material selected from among flame retardant 4 (FR-4), tetrafunctional epoxy, polyphenylene ether, epoxy/polyphenylene oxide, bismaleimide triazine (BT), Thermount, cyanate ester, polyimide, and liquid crystal polymer. Also, the first wiring pattern 130 may include copper, nickel, stainless steel, or beryllium copper.

The external connection bumps 160 may be disposed below the first wiring structure 100. The external connection bumps 160 may be electrically connected to an external device such as, for example, a motherboard. The external connection bumps 160 may be electrically connected to the first wiring pattern 130. The external connection bumps 160 may receive an electrical signal transmitted from the first semiconductor chip 200 and the second semiconductor chip 300 via the first wiring pattern 130 and may transmit the electrical signal to the external device. The first wiring pattern 130 may be electrically connected to the external device via the external connection bumps 160. The external connection bumps 160 may include a conductive material such as, for example, at least one from among solder, tin (Sn), silver (Ag), copper (Cu), and aluminum (Al).

The first semiconductor chip 200 may be mounted above the upper surface of the first wiring structure 100. The first semiconductor chip 200 may be electrically connected to the first wiring pattern 130. According to embodiments, the first semiconductor chip 200 may be mounted in a flip chip manner above the first wiring structure 100 via at least one chip connection bump 250, such as a micro bump. The first semiconductor chip 200 may be mounted in a flip chip manner above the first wiring structure 100 via a molded underfill (MUF) process. In other words, the molding member 490 may directly fill a gap between the first semiconductor chip 200 and the first wiring structure 100 while surrounding the at least one chip connection bump 250. However, in some embodiments, an underfill material layer surrounding the at least one chip connection bump 250 may be located between the first semiconductor chip 200 and the first wiring structure 100.

The first semiconductor chip 200 may include a memory chip or a logic chip. The memory chip may include, for example, volatile memory chips, such as dynamic random-access memory (DRAM) and static random-access memory (SRAM), or non-volatile memory chips, such as phase-change random-access memory (PRAM), magnetoresistive random-access memory (MRAM), ferroelectric random-access memory (FeRAM), and resistive random-access memory (RRAM). The logic chip may include, for example, microprocessors, such as a central processing unit (CPU), a graphics processing unit (GPU), and an application processor (AP), analog devices, or digital signal processors.

The second semiconductor chip 300 may be mounted above the first wiring structure 100 and spaced apart from the first semiconductor chip 200 in the first horizontal direction X and/or the second horizontal direction Y. The second semiconductor chip 300 may be electrically connected to the first wiring pattern 130. According to embodiments, the second semiconductor chip 300 may be mounted in a flip chip manner above the first wiring structure 100 via at least one chip connection bump 350, such as a micro bump. The second semiconductor chip 300 may be mounted in a flip chip manner above the first wiring structure 100 via an MUF process. In other words, the molding member 490 may directly fill a gap between the second semiconductor chip 300 and the first wiring structure 100 while surrounding the at least one chip connection bump 350. However, in some embodiments, an underfill material layer surrounding the at least one chip connection bump 350 may be located between the second semiconductor chip 300 and the first wiring structure 100. The second semiconductor chip 300 may include a memory chip or a logic chip.

The adhesive layer 550 may be disposed on the upper surface of each of the first semiconductor chip 200 and the second semiconductor chip 300. The adhesive layer 550 may be configured to bond the heat dissipation member 600 to the first semiconductor chip 200 and bond the heat dissipation member 600 to the second semiconductor chip 300. According to embodiments, the adhesive layer 550 may include a film having self-adhesive characteristics. For example, the adhesive layer 550 may include a double-sided adhesive film. According to embodiments, the adhesive layer 550 may include a tape-shaped material layer, a liquid coating-hardened material layer, or a combination thereof. In addition, the adhesive layer 550 may include a thermal setting structure, thermal plastics, an ultraviolet (UV) cure material, or a combination thereof. The adhesive layer 550 may be a die attach film (DAF) or a non-conductive film (NCF). According to embodiments, the adhesive layer 550 may include a high-k die attach film. According to embodiments, the thermal conductivity of the adhesive layer 550 may be greater than the thermal conductivity of the molding member 490.

The molding member 490 may surround the first semiconductor chip 200, the second semiconductor chip 300, and the adhesive layer 550 on the upper surface of the first wiring structure 100. According to embodiments, the molding member 490 may cover the side surface of the first semiconductor chip 200, the side surface of the second semiconductor chip 300, and the side surface of the adhesive layer 550, but the upper surface of the adhesive layer 550 may not be in contact with the molding member 490.

The molding member 490 may include thermosetting resin, such as epoxy resin, thermoplastic resin, such as polyimide, or resin formed by adding a reinforcing material, such as an inorganic filler, into the thermosetting resin or the thermoplastic resin, and specifically, may include an Ajinomoto build-up film (ABF), FR-4, BT, etc., but embodiments of the present disclosure are not limited thereto. Also, the molding member 490 may include a molding material, such as an epoxy mold compound (EMC), or a photosensitive material, such as a photoimagable encapsulant (PIE). In some embodiments, the molding member 490 may partially include an insulating material, such as a silicon oxide layer, a silicon nitride layer, and a silicon oxynitride layer.

The heat dissipation member 600 may be provided on the upper surfaces of the molding member 490 and the adhesive layer 550. The heat dissipation member 600 may include a heat slug or a heat sink. In embodiments, the heat dissipation member 600 may include a flat metal plate or a three-dimensional metal structure. The heat dissipation member 600 may include any one material selected from among high thermal conductivity materials such as, for example, copper, a copper alloy, aluminum, an aluminum alloy, steel, stainless steel, and a combination thereof.

In some embodiments, the heat dissipation member 600 may not include a seed metal layer. The heat dissipation member 600 may be attached to the first semiconductor chip 200 and the second semiconductor chip 300 via the adhesive layer 550 and may not be formed by the seed metal layer. In some embodiments, the heat dissipation member 600 may not be formed through a sputtering process. In other words, the heat dissipation member 600 may be attached to the first semiconductor chip 200 and the second semiconductor chip 300 through the adhesive layer 550 after manufacturing pure metal. Accordingly, the heat dissipation member 600 may be strongly bonded to the first semiconductor chip 200 and the second semiconductor chip 300, and may be resistant to corrosion and excellent in preventing water permeation.

According to a comparative embodiment, when a heat dissipation member is disposed on a first semiconductor chip and a second semiconductor chip, the heat dissipation member is attached to the first semiconductor chip and the second semiconductor chip 300 through a sputtering process, or a seed metal layer is formed on the upper surface of each of the first semiconductor chip and the second semiconductor chip so that the heat dissipation member is attached thereto. In such cases, adhesive strength issues arise between the heat dissipation member and the first semiconductor chip and between the heat dissipation member and the second semiconductor chip. Also, gaps are formed between the heat dissipation member 600 and the first semiconductor chip and the second semiconductor chip, which may lead to water permeation and corrosion.

However, in the semiconductor package 10 according to an embodiment of the present disclosure, the heat dissipation member 600 may be fixed to the first semiconductor chip 200 and the second semiconductor chip 300 via the adhesive layer 550, and the adhesive layer 550 may easily discharge heat generated inside the semiconductor package 10 to the outside using a high-k DAF.

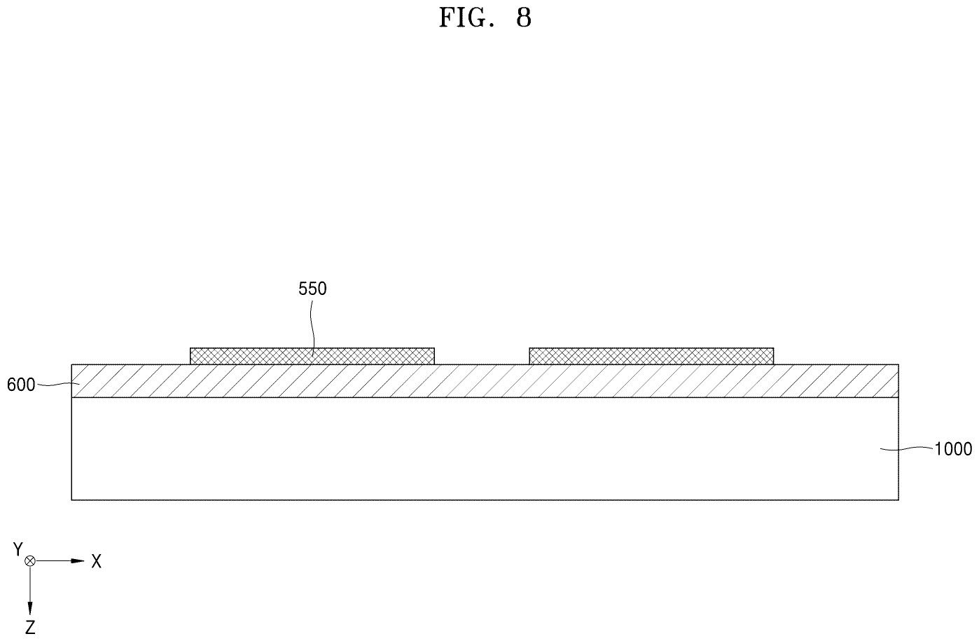

Furthermore, in the semiconductor package 10 according to an embodiment of the present disclosure, adhesion between the heat dissipation member 600 and the semiconductor chips (e.g., the first semiconductor chip 200 and the second semiconductor chip 300) is made first, and then the first wiring structure 100 is formed as described below with reference to FIG. 8. Therefore, the adhesion between the heat dissipation member 600 and the semiconductor chips (e.g., the first semiconductor chip 200 and the second semiconductor chip 300) may be made more easily and effectively.

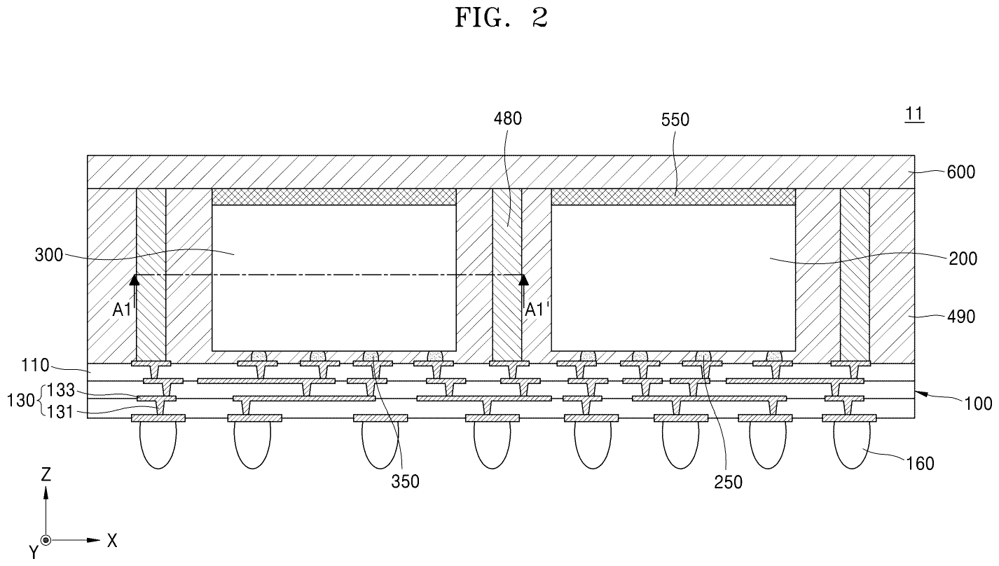

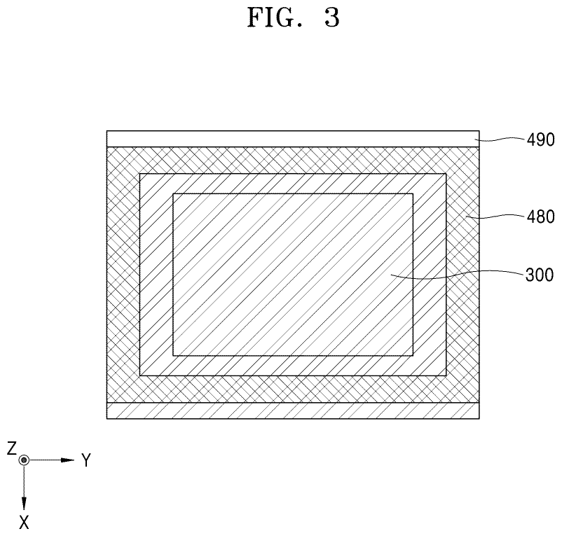

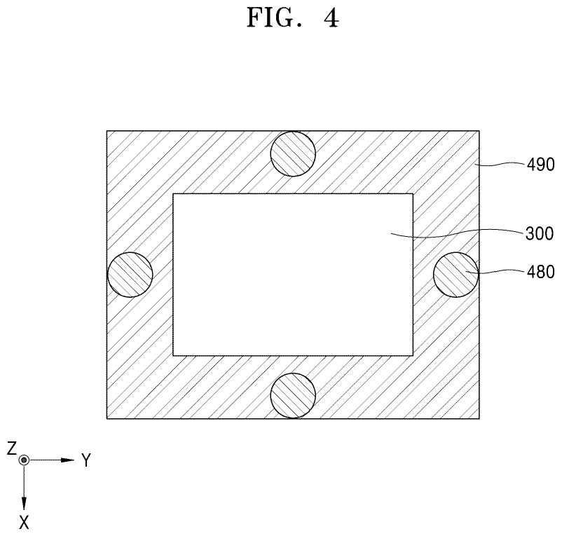

FIG. 2 is a cross-sectional view showing a semiconductor package 11 according to an embodiment. FIG. 3 is a cross-sectional view showing one example of the semiconductor package 11 taken along a line A1-A1′ of FIG. 2. FIG. 4 is a cross-sectional view showing one example of the semiconductor package 11 taken along the line A1-A1′ of FIG. 2. In the description below, the differences between the semiconductor package 10 of FIG. 1 and the semiconductor package 11 of FIGS. 2 to 4 are mainly described.

Referring to FIGS. 2 to 5, the semiconductor package 11 according to an embodiment of the present disclosure may include a first wiring structure 100, a first semiconductor chip 200, a second semiconductor chip 300, an adhesive layer 550, a dummy block 480, and a heat dissipation member 600.

The first wiring structure 100 may be disposed below the first semiconductor chip 200 and the second semiconductor chip 300, and may electrically connect the first semiconductor chip 200 to at least one external connection bump 160 and electrically connect the second semiconductor chip 300 to the at least one external connection bump 160. The first wiring structure 100 may include a first wiring insulating layer 110 and a first wiring pattern 130. The first wiring pattern 130 may include a first wiring via 131 and a first wiring line 133. In some embodiments, the first wiring structure 100 may include a redistribution structure manufactured through a redistribution process. In some embodiments, the first wiring structure 100 may include a PCB. The external connection bump 160 may be disposed below the first wiring structure 100. The first semiconductor chip 200 may be mounted above the upper surface of the first wiring structure 100. The second semiconductor chip 300 may be mounted above the first wiring structure 100 and spaced apart from the first semiconductor chip 200 in the first horizontal direction X and/or the second horizontal direction Y.

An adhesive layer 550 may be disposed on the upper surface of each of the first semiconductor chip 200 and the second semiconductor chip 300. The adhesive layer 550 may be configured to bond the heat dissipation member 600 to the first semiconductor chip 200 and bond the heat dissipation member 600 to the second semiconductor chip 300. According to embodiments, the adhesive layer 550 may include a high-k die attach film.

The dummy block 480 may have a shape extending in the vertical direction Z on the first wiring structure 100. The dummy block 480 may be spaced apart from each of the first semiconductor chip 200 and the second semiconductor chip 300.

The dummy block 480 may not be electrically connected to the first wiring pattern 130. That is, the dummy block 480 may not exchange signals with the first semiconductor chip 200, the second semiconductor chip 300, and the external connection bumps 160.

According to embodiments, the dummy block 480 may include metal. For example, the dummy block 480 may include copper (Cu), aluminum (Al), gold (Au), silver (Ag), etc.

According to embodiments, the dummy block 480 may surround the second semiconductor chip 300, as shown in FIG. 3. The dummy block 480 and the second semiconductor chip 300 are shown in FIG. 3 for convenience of description, and the dummy block 480 may surround the first semiconductor chip 200 in the same manner. Consequently, the dummy block 480 may surround each of the first semiconductor chip 200 and the second semiconductor chip 300. The dummy block 480 may surround the first semiconductor chip 200 while being spaced apart from the first semiconductor chip 200 in the first horizontal direction X and/or the second horizontal direction Y. Also, the dummy block 480 may surround the second semiconductor chip 300 while being spaced apart from the second semiconductor chip 300 in the first horizontal direction X and/or the second horizontal direction Y. According to embodiments, the cross-section of the dummy block 480 on the X-Y plane may include a quadrangular ring shape. According to embodiments, the cross-section of the dummy block 480 on the X-Y plane may have a shape in which two quadrangular rings are continuously attached to each other in the first horizontal direction X. Similarly, the cross-section of the dummy block 480 on the X-Y plane may have a shape that is obtained by rotating the number 8 by 90 degrees. A molding member 490 may be located between the first semiconductor chip 200 and the dummy block 480 and between the second semiconductor chip 300 and the dummy block 480.

According to embodiments, the dummy block 480 may have a pillar shape extending in the vertical direction Z without surrounding the first semiconductor chip 200 and the second semiconductor chip 300. According to embodiments, the dummy block 480 may have a cylindrical shape as shown in FIG. 4. However, the shape of the dummy block 480 is not limited thereto, and the dummy block 480 may have a polygonal pillar shape. FIG. 4 shows that four dummy blocks 480 are provided, but the number of dummy blocks 480 is not limited thereto.

The molding member 490 may surround the first semiconductor chip 200, the second semiconductor chip 300, the dummy block 480, and the adhesive layer 550 on the upper surface of the first wiring structure 100. According to embodiments, the molding member 490 may cover the side surface of the first semiconductor chip 200, the side surface of the second semiconductor chip 300, the side surface of the dummy block 480, and the side surface of the adhesive layer 550, but the upper surface of the adhesive layer 550 may not be in contact with the molding member 490.

The heat dissipation member 600 may be in contact with the upper surface of each of the molding member 490, the dummy block 480, and the adhesive layer 550. The heat dissipation member 600 may include a heat slug or a heat sink.

In the semiconductor package 11 according to an embodiment of the present disclosure, the heat dissipation member 600 may be bonded to the first semiconductor chip 200 and the second semiconductor chip 300 via the adhesive layer 550, and the heat generated inside the semiconductor package 11 may be transferred to the heat dissipation member 600 via the dummy block 480 that is formed on the first wiring structure 100. Accordingly, the thermal characteristics of the semiconductor package 11 may be enhanced.

Furthermore, since the dummy block 480 is formed on the first wiring structure 100, warpage of the semiconductor package 11 may prevented from occurring, and moisture may be efficiently prevented from permeating into the molding member 490, the first semiconductor chip 200, and the second semiconductor chip 300.

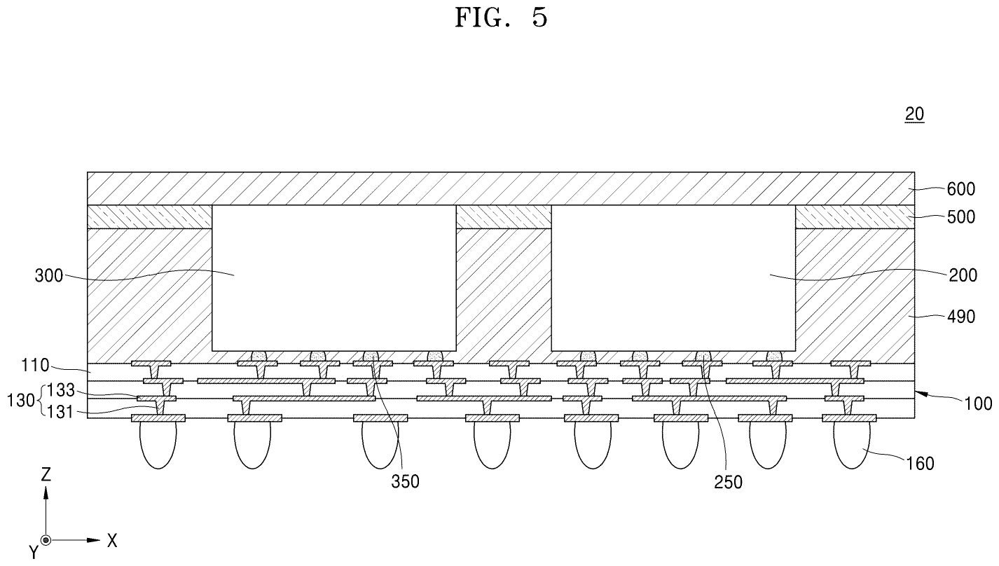

FIG. 5 is a cross-sectional view showing a semiconductor package 20 according to an embodiment. In the description below, the differences between the semiconductor package 10 of FIG. 1 and the semiconductor package 20 of FIG. 5 are mainly described.

Referring to FIG. 5, the semiconductor package 20 may include a first wiring structure 100, a first semiconductor chip 200, a second semiconductor chip 300, a molding film 500, and a heat dissipation member 600.

The first wiring structure 100 may be disposed below the first semiconductor chip 200 and the second semiconductor chip 300, and may electrically connect the first semiconductor chip 200 to at least one external connection bump 160 and electrically connect the second semiconductor chip 300 to the at least one external connection bump 160. The first wiring structure 100 may include a first wiring insulating layer 110 and a first wiring pattern 130. The first wiring pattern 130 may include a first wiring via 131 and a first wiring line 133. In some embodiments, the first wiring structure 100 may include a redistribution structure manufactured through a redistribution process. In some embodiments, the first wiring structure 100 may include a PCB. The external connection bump 160 may be disposed below the first wiring structure 100. The first semiconductor chip 200 may be mounted above the upper surface of the first wiring structure 100. The second semiconductor chip 300 may be mounted above the first wiring structure 100 and spaced apart from the first semiconductor chip 200 in the first horizontal direction X and/or the second horizontal direction Y.

The upper surface of each of the first semiconductor chip 200 and the second semiconductor chip 300 may be in contact with the heat dissipation member 600. The adhesive layer 550 (see FIG. 1) may not be provided between the heat dissipation member 600 and the upper surface of each of the first semiconductor chip 200 and the second semiconductor chip 300.

According to embodiments, the molding film 500 may be located on the lower surface of the heat dissipation member 600. The lower surface of the heat dissipation member 600 may be in contact with the molding film 500, the upper surface of the first semiconductor chip 200, and the upper surface of the second semiconductor chip 300.

The molding film 500 may surround the upper portions of the side surfaces of the first semiconductor chip 200 and the second semiconductor chip 300. The molding film 500 may be self-adhesive and include polymeric materials, such as, for example, polyimide, polyurethane, and epoxy. According to embodiments, the thermal conductivity of the molding film 500 may be greater than the thermal conductivity of the molding member 490. According to embodiments, the molding film 500 may be a high-k molding film. For example, the molding film 500 (e.g., the high-k molding film) may include a material having a high thermal conductivity among carbon-based materials. The heat dissipation member 600 may be bonded to the first semiconductor chip 200 and the second semiconductor chip 300 via the molding film 500. The molding member 490 may surround the first semiconductor chip 200 and the second semiconductor chip 300 on the upper surface of the first wiring structure 100. The molding film 500 may be disposed on the upper surface of the molding member 490. The molding film 500 may be located between the molding member 490 and the heat dissipation member 600.

The heat dissipation member 600 may be disposed on the upper surface of the molding film 500, the upper surface of the first semiconductor chip 200, and the upper surface of the second semiconductor chip 300. The heat dissipation member 600 may include a heat slug or a heat sink.

In the semiconductor package 20 according to an embodiment of the present disclosure, the heat dissipation member 600 may be bonded to the first semiconductor chip 200 and the second semiconductor chip 300 via the molding film 500. In addition, since the molding film 500 may have a high thermal conductivity, the heat generated in the semiconductor package 20 may be efficiently transferred to the heat dissipation member 600.

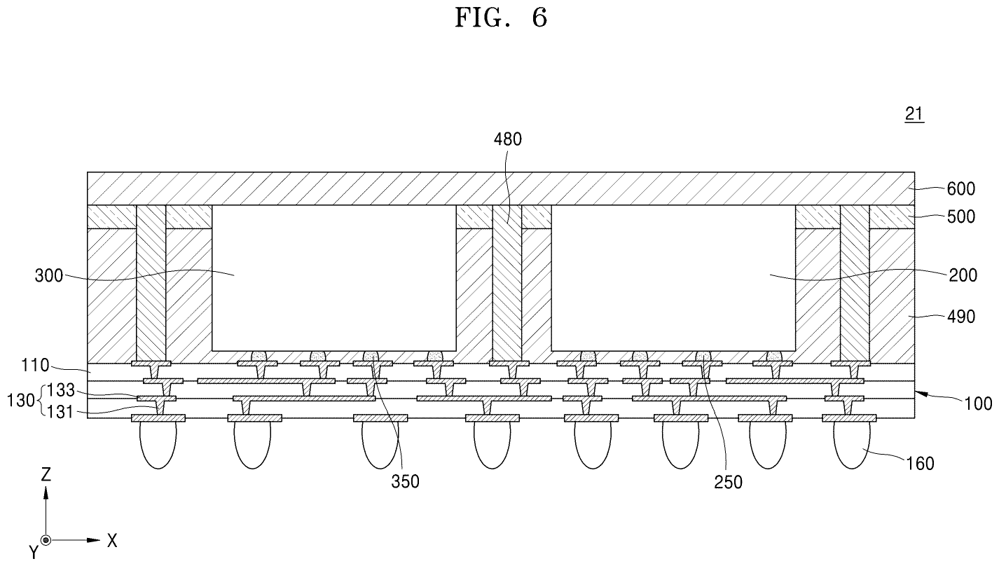

FIG. 6 is a cross-sectional view showing a semiconductor package 21 according to an embodiment. In the description below, the differences between the semiconductor package 20 of FIG. 5 and the semiconductor package 21 of FIG. 6 are mainly described.

Referring to FIG. 6, the semiconductor package 21 may include a first wiring structure 100, a first semiconductor chip 200, a second semiconductor chip 300, a molding film 500, a dummy block 480, and a heat dissipation member 600.

The first wiring structure 100 may be disposed below the first semiconductor chip 200 and the second semiconductor chip 300, and may electrically connect the first semiconductor chip 200 to at least one external connection bump 160 and electrically connect the second semiconductor chip 300 to the at least one external connection bump 160. The first wiring structure 100 may include a first wiring insulating layer 110 and a first wiring pattern 130. The first wiring pattern 130 may include a first wiring via 131 and a first wiring line 133. In some embodiments, the first wiring structure 100 may include a redistribution structure manufactured through a redistribution process. In some embodiments, the first wiring structure 100 may include a PCB. The external connection bumps 160 may be disposed below the first wiring structure 100. The first semiconductor chip 200 may be mounted above the upper surface of the first wiring structure 100. The second semiconductor chip 300 may be mounted above the first wiring structure 100 and spaced apart from the first semiconductor chip 200 in the first horizontal direction X and/or the second horizontal direction Y.

The molding film 500 may surround the upper portions of the side surfaces of the first semiconductor chip 200, the second semiconductor chip 300, and the dummy block 480. The molding film 500 may be self-adhesive and include polymeric materials, such as, for example, polyimide, polyurethane, and epoxy. According to embodiments, the molding film 500 may be a high-k molding film. For example, the molding film 500 (e.g., the high-k molding film) may include a material having a high thermal conductivity among carbon-based materials. The heat dissipation member 600 may be bonded to the first semiconductor chip 200 and the second semiconductor chip 300 via the molding film 500. The molding member 490 may surround the first semiconductor chip 200, the second semiconductor chip 300, and the dummy block 480 on the upper surface of the first wiring structure 100. The molding film 500 may be disposed on the upper surface of the molding member 490. The molding film 500 may be located between the molding member 490 and the heat dissipation member 600.

The dummy block 480 may have a shape extending in the vertical direction Z on the first wiring structure 100. The dummy block 480 may pass through the molding member 490 and the molding film 500 in the vertical direction Z on the first wiring structure 100. The dummy block 480 may be spaced apart from each of the first semiconductor chip 200 and the second semiconductor chip 300.

The dummy block 480 may not be electrically connected to the first wiring pattern 130. That is, the dummy block 480 may not exchange signals with the first semiconductor chip 200, the second semiconductor chip 300, and the at least one external connection bump 160.

According to embodiments, the dummy block 480 may include metal. For example, the dummy block 480 may include copper, aluminum, gold, silver, etc.

According to embodiments, the dummy block 480 may surround each of the first semiconductor chip 200 and the second semiconductor chip 300. The dummy block 480 may surround the first semiconductor chip 200 while being spaced apart from the first semiconductor chip 200 in the first horizontal direction X and/or the second horizontal direction Y. Also, the dummy block 480 may surround the second semiconductor chip 300 while being spaced apart from the second semiconductor chip 300 in the first horizontal direction X and/or the second horizontal direction Y. According to embodiments, the cross-section of the dummy block 480 on the X-Y plane may include a quadrangular ring shape. According to embodiments, the cross-section of the dummy block 480 on the X-Y plane may have a shape in which two quadrangular rings are continuously attached to each other in the first horizontal direction X. Similarly, the cross-section of the dummy block 480 on the X-Y plane may have a shape that is obtained by rotating the number 8 by 90 degrees. The molding member 490 may be located between the first semiconductor chip 200 and the dummy block 480 and between the second semiconductor chip 300 and the dummy block 480.

According to embodiments, the dummy block 480 may have a pillar shape extending in the vertical direction Z without surrounding the first semiconductor chip 200 and the second semiconductor chip 300. According to embodiments, the dummy block 480 may have a cylindrical shape. However, the shape of the dummy block 480 is not limited thereto, and the dummy block 480 may have a polygonal pillar shape. FIG. 4 shows that four dummy blocks 480 are provided, but the number of dummy blocks 480 is not limited thereto.

The heat dissipation member 600 may be in contact with the upper surface of each of the molding film 500, the dummy block 480, the first semiconductor chip 200, and second semiconductor chip 300. The heat dissipation member 600 may include a heat slug or a heat sink.

In the semiconductor package 21 according to an embodiment of the present disclosure, the heat dissipation member 600 may be bonded to the first semiconductor chip 200 and the second semiconductor chip 300 via the molding film 500. In addition, heat generated inside the semiconductor package 21 may be transferred to the heat dissipation member 600 via the dummy block 480 formed on the first wiring structure 100. Accordingly, the thermal characteristics of the semiconductor package 21 may be enhanced.

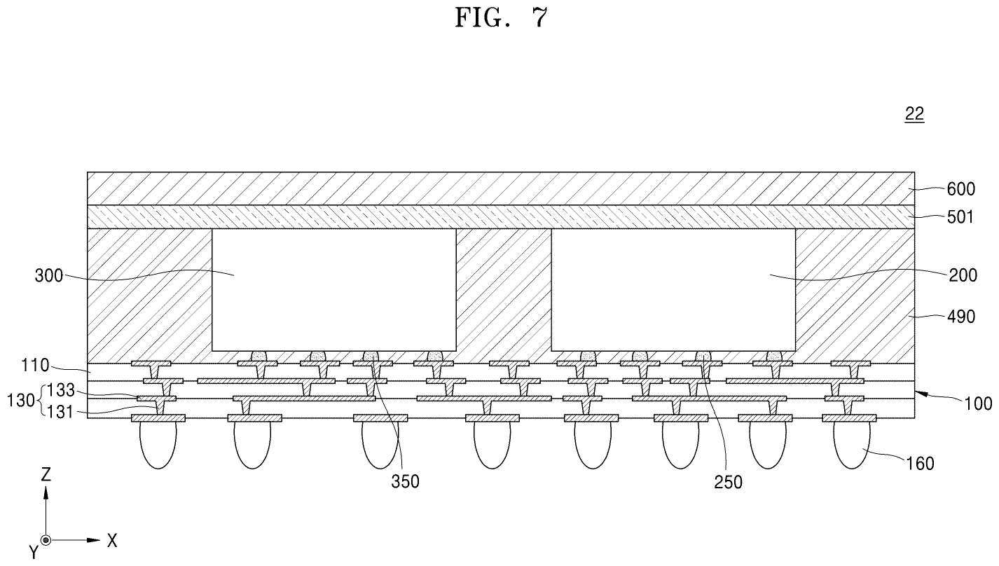

FIG. 7 is a cross-sectional view showing a semiconductor package 22 according to an embodiment. In the description below, the differences between the semiconductor package 20 of FIG. 5 and the semiconductor package 22 of FIG. 7 are mainly described.

Referring to FIG. 7, the semiconductor package 22 may include a first wiring structure 100, a first semiconductor chip 200, a second semiconductor chip 300, a molding film 501, and a heat dissipation member 600.

The first wiring structure 100 may be disposed below the first semiconductor chip 200 and the second semiconductor chip 300, and may electrically connect the first semiconductor chip 200 to at least one external connection bump 160 and electrically connect the second semiconductor chip 300 to the at least one external connection bump 160. The first wiring structure 100 may include a first wiring insulating layer 110 and a first wiring pattern 130. The first wiring pattern 130 may include a first wiring via 131 and a first wiring line 133. In some embodiments, the first wiring structure 100 may include a redistribution structure manufactured through a redistribution process. In some embodiments, the first wiring structure 100 may include a PCB. The at least one external connection bump 160 may be disposed below the first wiring structure 100. The first semiconductor chip 200 may be mounted above the upper surface of the first wiring structure 100. The second semiconductor chip 300 may be mounted above the first wiring structure 100 and spaced apart from the first semiconductor chip 200 in the first horizontal direction X and/or the second horizontal direction Y.

The upper surface of each of the first semiconductor chip 200 and the second semiconductor chip 300 may be in contact with the heat dissipation member 600. The adhesive layer 550 (see FIG. 1) may not be provided between the heat dissipation member 600 and the upper surface of each of the first semiconductor chip 200 and the second semiconductor chip 300.

According to embodiments, the molding film 501 may be located on the lower surface of the heat dissipation member 600. The molding film 501 may be in contact with the upper surface of each of the first semiconductor chip 200, the second semiconductor chip 300, and the molding member 490. The heat dissipation member 600 may be spaced apart from each of the molding member 490, the first semiconductor chip 200, and the second semiconductor chip 300 in the vertical direction Z with the molding film 501 therebetween. The molding film 501 may be provided between the heat dissipation member 600 and the first semiconductor chip 200, between the heat dissipation member 600 and the second semiconductor chip 300, and between the heat dissipation member 600 and the molding member 490.

The molding film 501 may be self-adhesive and include polymeric materials, such as, for example, polyimide, polyurethane, and epoxy. According to embodiments, the molding film 501 may be a high-k molding film. The heat dissipation member 600 may be bonded to the first semiconductor chip 200, the second semiconductor chip 300, and the molding member 490 via the molding film 501.

In the semiconductor package 22 according to an embodiment of the present disclosure, the molding film 501 may be located on the upper surfaces of the first semiconductor chip 200, the second semiconductor chip 300, and the molding member 490 and may be located on the lower surface of the heat dissipation member 600. In addition, the molding film 501 may not include a hole and may have a shape extending in the first horizontal direction X and/or the second horizontal direction Y. Accordingly, the area in which the heat dissipation member 600 is in contact with the molding film 501 increases, and thus, the heat dissipation member 600 may be more firmly bonded to the molding film 501. In addition, the molding film 501 may include a material with high thermal conductivity, and thus, heat generated inside the semiconductor package 22 may be more efficiently transferred to the heat dissipation member 600.

FIGS. 8 to 13 are cross-sectional views illustrating a method of manufacturing the semiconductor package 10 of FIG. 1. Hereinafter, repeated descriptions as those given with reference to FIG. 1 may be omitted, and the description may focus on the differences. Descriptions of directions (e.g., “upper” and “lower”) given below with reference to FIGS. 8 to 13 may be provided to correspond with the orientations of FIGS. 8 to 13.

Referring to FIG. 8, a heat dissipation member 600 may be mounted on a carrier substrate 1000. An adhesive layer 550 may be provided on the upper surface of the heat dissipation member 600. According to embodiments, the carrier substrate 1000 may include polyimide, glass, etc. The adhesive layer 550 may include a plurality of portions that are continuous or non-contiguous with respect to each other. The number of the portions of the adhesive layer 550 may be equal to the number of semiconductor chips to be mounted in the package.

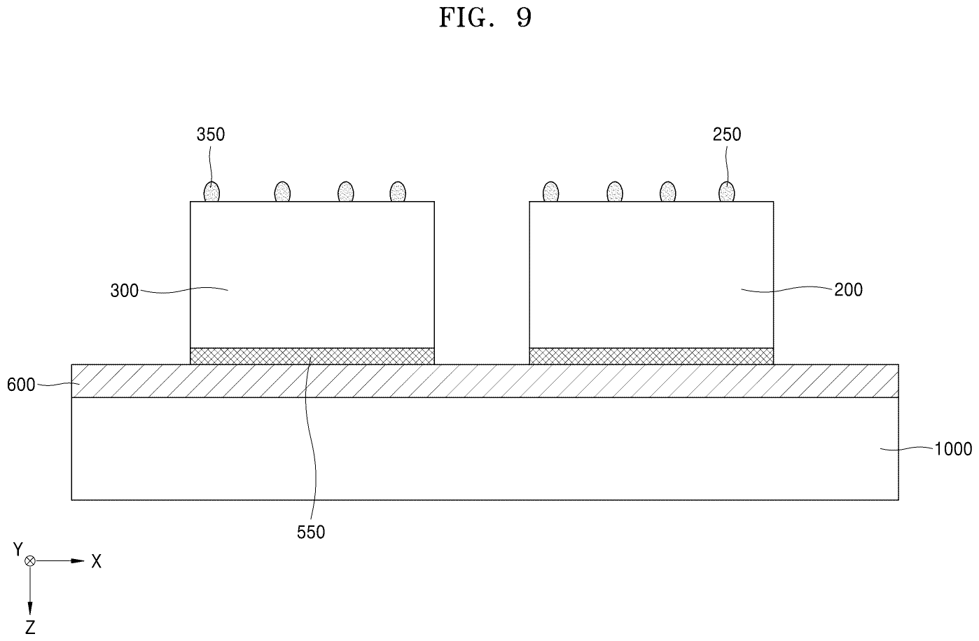

Referring to FIG. 9, a first semiconductor chip 200 and a second semiconductor chip 300 may be attached to the adhesive layer 550. Chip connection bumps 250 and 350 may be provided on the upper surface of the first semiconductor chip 200 and the upper surface of the second semiconductor chip 300, respectively. According to embodiments, the footprint (e.g., an area in a plan view) of a first portion of the adhesive layer 550 in contact with the first semiconductor chip 200 may be substantially the same as the footprint of the first semiconductor chip 200. Also, the footprint of a second portion of the adhesive layer 550 in contact with the second semiconductor chip 300 may be substantially the same as the footprint of the second semiconductor chip 300.

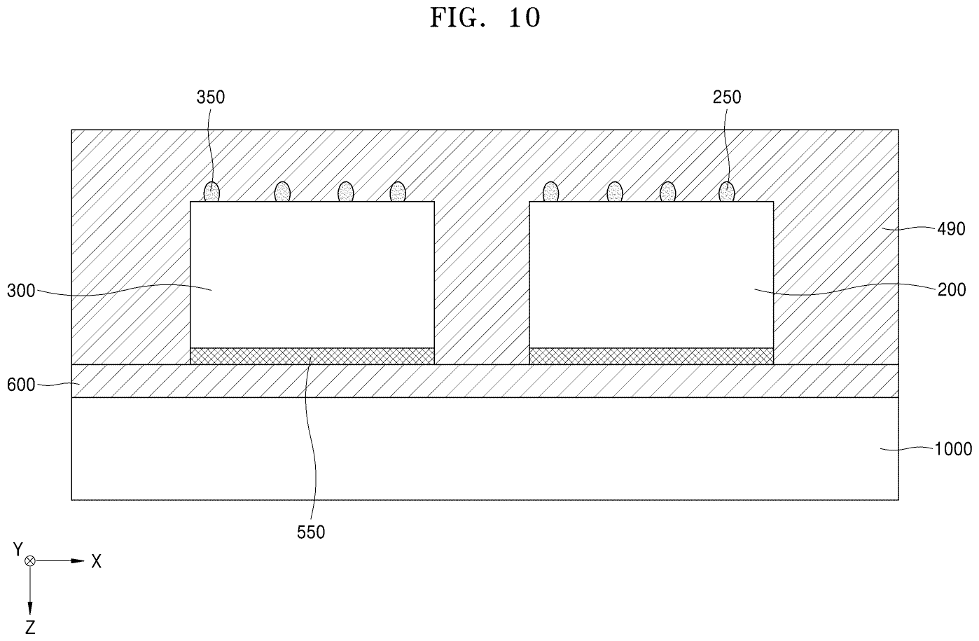

Referring to FIG. 10, a molding member 490 may be formed, which may cover the adhesive layer 550, the first semiconductor chip 200, and the second semiconductor chip 300. The molding member 490 may cover the upper surface of the heat dissipation member 600, and may cover the side surfaces of the adhesive layer 550 and the side surfaces and upper surface of each of the first semiconductor chip 200 and the second semiconductor chip 300. The molding member 490 may surround the chip connection bumps 250 and 350.

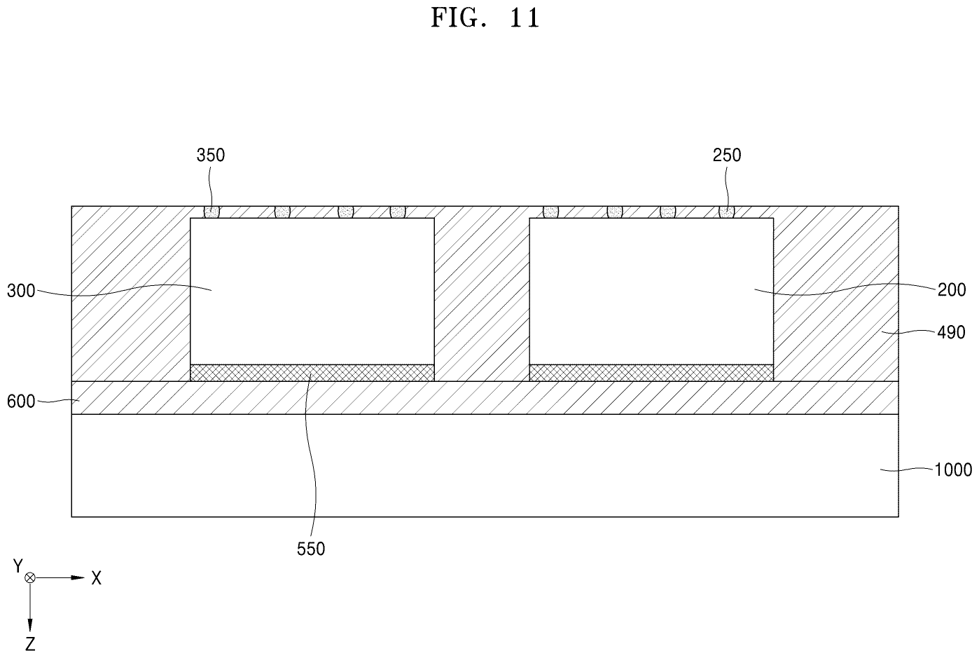

Referring to FIG. 11, the molding member 490 may be etched to at least a certain depth. The molding member 490 may be etched through a chemical mechanical polishing (CMP) process or the like. Etching of the molding member 490 may continue so that the chip connection bumps 250 and 350 are partially etched. Accordingly, the chip connection bumps 250 and 350 may be exposed from the molding member 490 in the vertical direction Z. In this case, surfaces of the chip connection bumps 250 and 350 that are not in contact with the first semiconductor chip 200 and the second semiconductor chip 300 may be flat. For example, surfaces of the chip connection bumps 250 and 350 that face away from the first semiconductor chip 200 and the second semiconductor chip 300 may be flat.

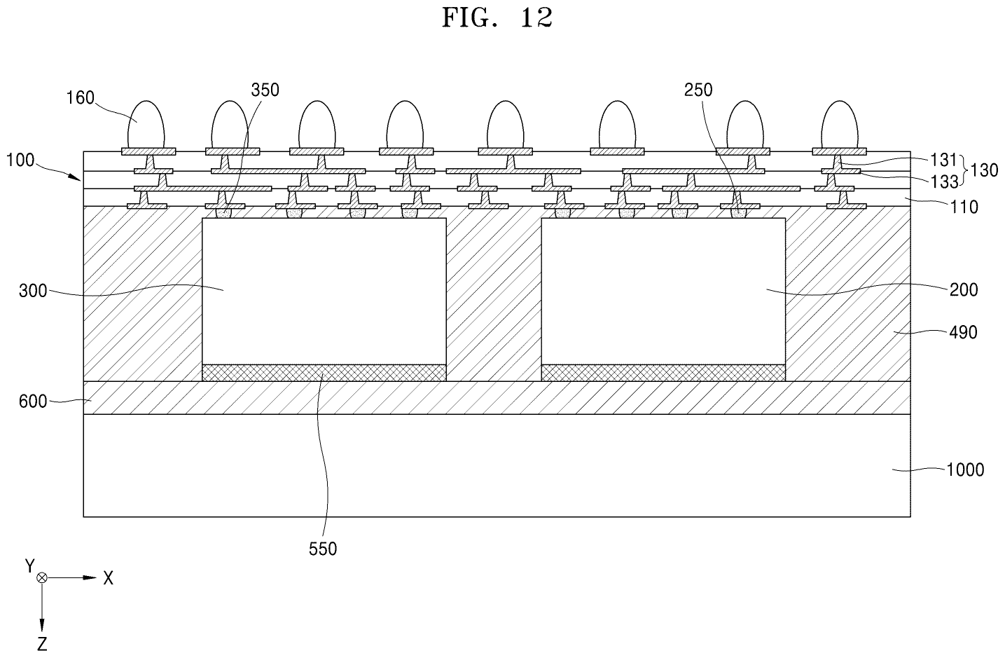

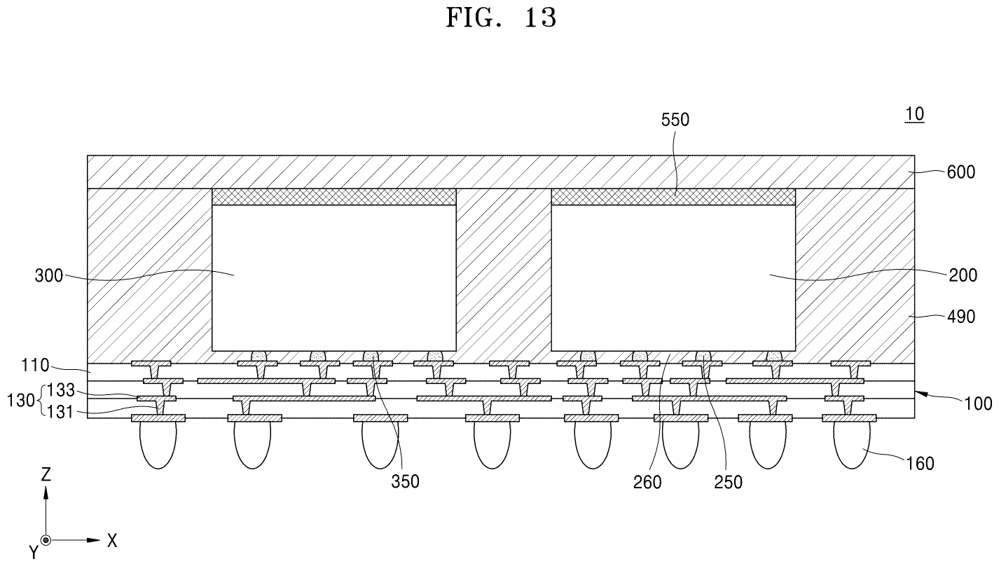

Referring to FIGS. 12 and 13, a first wiring structure 100 may be formed on the molding member 490. The first wiring structure 100 may include a first wiring pattern 130 and a first wiring insulating layer 110. The first wiring structure 100 may include a PCB or a redistribution structure formed through a redistribution process. The flat surfaces of the chip connection bumps 250 and 350 may be electrically connected to the first wiring pattern 130. Subsequently, the carrier substrate 1000 may be removed, and the semiconductor package 10 is completed.

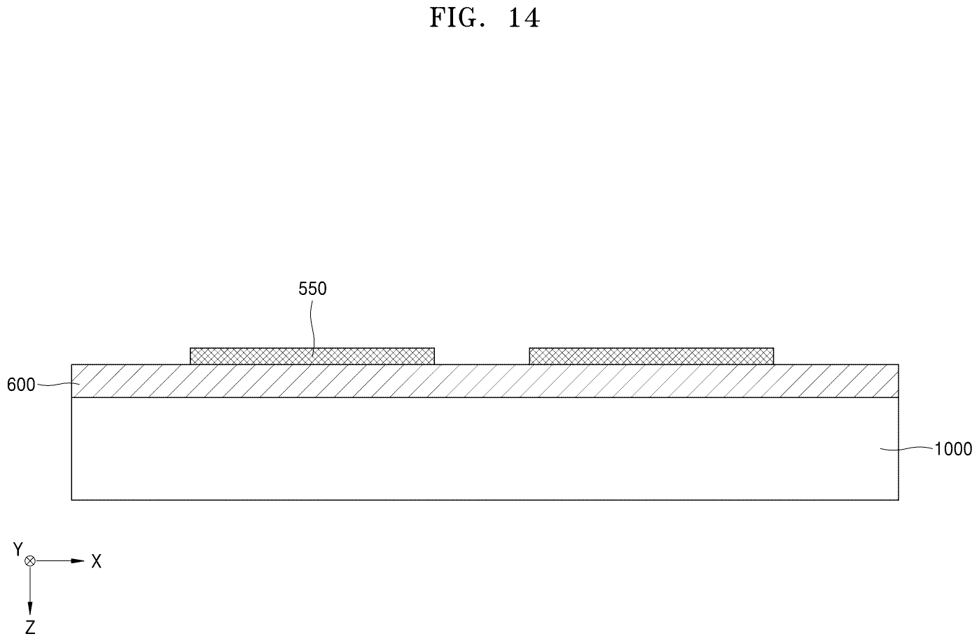

FIGS. 14 to 19 are cross-sectional views illustrating a method of manufacturing the semiconductor package 11 of FIG. 2. Hereinafter, repeated descriptions as those given with reference to FIG. 2 may be omitted, and the description may focus on the differences. Descriptions of directions (e.g., “upper” and “lower”) given below with reference to FIGS. 14 to 19 may be provided to correspond with the orientations of FIGS. 14 to 19.

Referring to FIG. 14, a heat dissipation member 600 may be mounted on a carrier substrate 1000. An adhesive layer 550 may be provided on the upper surface of the heat dissipation member 600. According to embodiments, the carrier substrate 1000 may include polyimide, glass, etc. The adhesive layer 550 may include a plurality of portions that are contiguous and/or non-contiguous with respect to each other. The number of the portions of the adhesive layer 550 may be equal to the number of semiconductor chips to be mounted in the package.

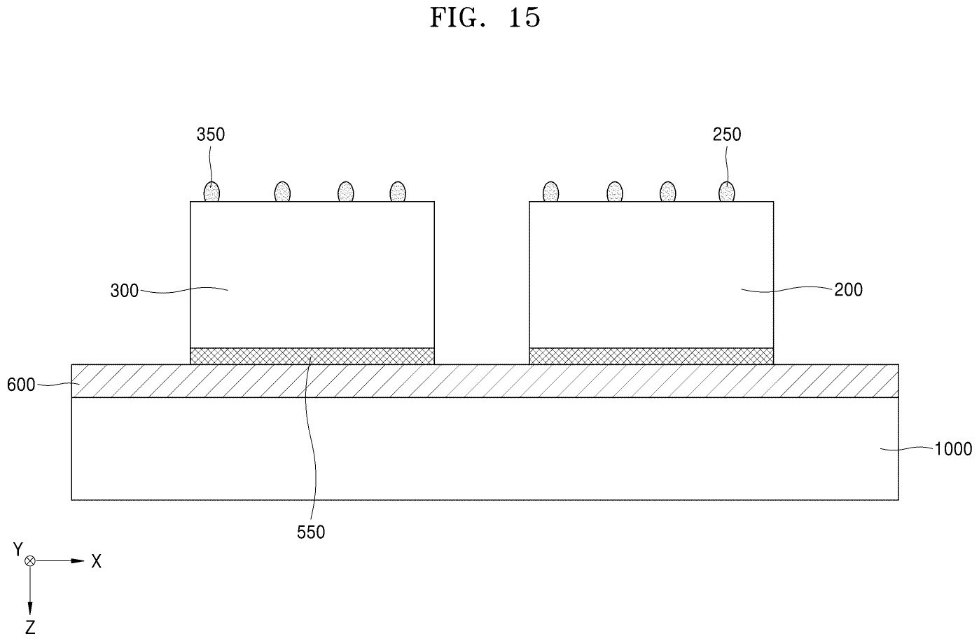

Referring to FIG. 15, a first semiconductor chip 200 and a second semiconductor chip 300 may be attached to the adhesive layer 550. Chip connection bumps 250 and 350 may be provided on the upper surface of the first semiconductor chip 200 and the upper surface of the second semiconductor chip 300, respectively. According to embodiments, the footprint of a first portion of the adhesive layer 550 in contact with the first semiconductor chip 200 may be substantially the same as the footprint of the first semiconductor chip 200. Also, the footprint of a second portion of the adhesive layer 550 in contact with the second semiconductor chip 300 may be substantially the same as the footprint of the second semiconductor chip 300.

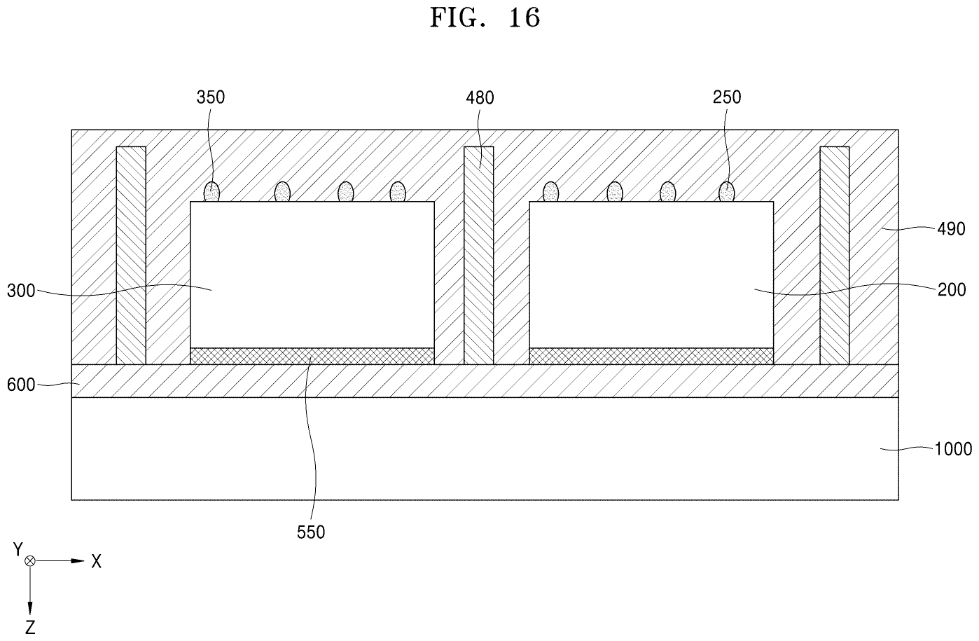

Referring to FIG. 16, a dummy block 480 may be formed on the heat dissipation member 600. The dummy block 480 may be spaced apart from each of the first semiconductor chip 200 and the second semiconductor chip 300 in the first horizontal direction X and/or the second horizontal direction Y. Subsequently, a molding member 490 may be formed, which may cover the adhesive layer 550, the dummy block 480, the first semiconductor chip 200, and second semiconductor chip 300. The molding member 490 may surround the chip connection bumps 250 and 350.

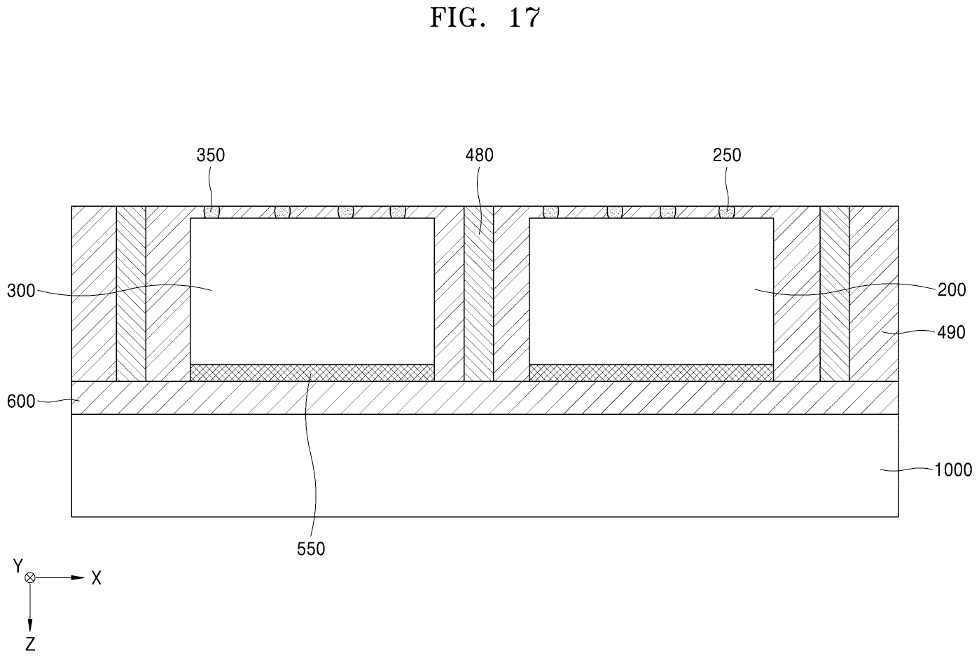

Referring to FIG. 17, the molding member 490 may be etched to at least a certain depth. The molding member 490 may be etched through a CMP process or the like. Etching of the molding member 490 may continue so that the chip connection bumps 250 and 350 are partially etched. Accordingly, the chip connection bumps 250 and 350 may be exposed from the molding member 490 in the vertical direction Z. In this case, the surfaces of the chip connection bumps 250 and 350 that are not in contact with the first semiconductor chip 200 and the second semiconductor chip 300 may be flat. While the molding member 490 is etched, the dummy block 480 may also be partially etched. The upper surfaces of the dummy block 480, the molding member 490, and the chip connection bumps 250 and 350 may be coplanar with each other.

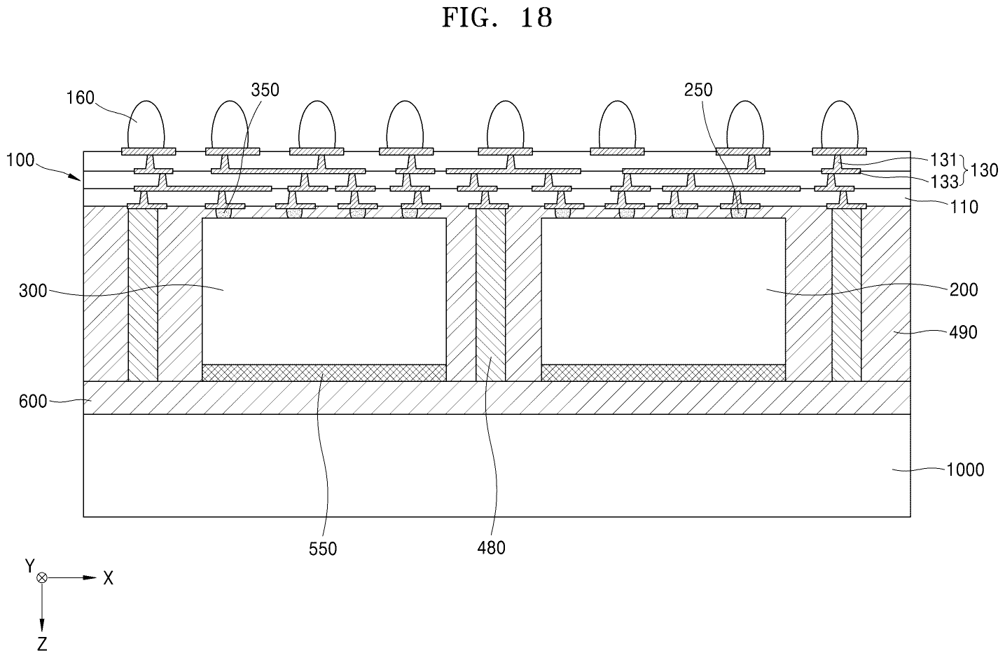

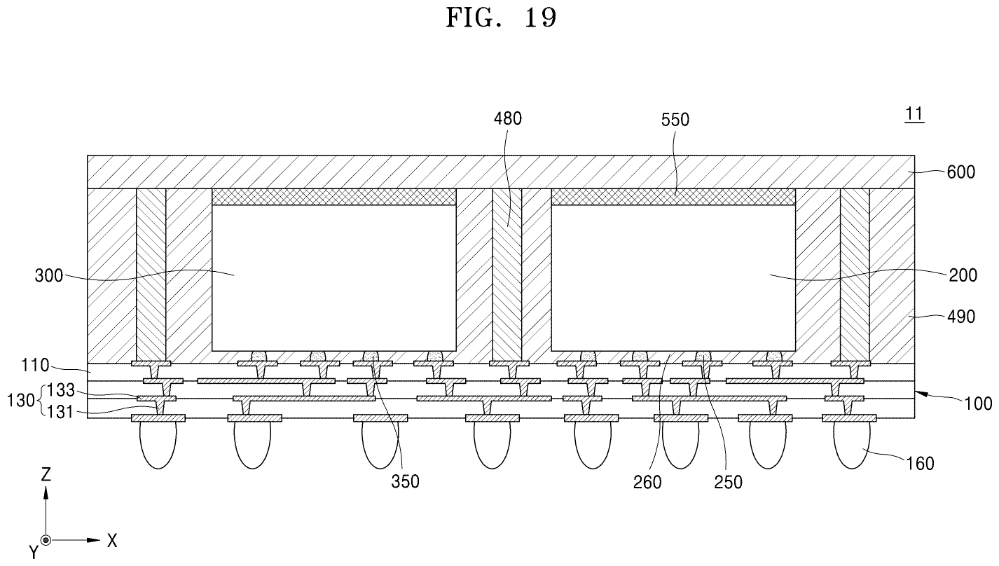

Referring to FIGS. 18 and 19, a first wiring structure 100 may be formed on the molding member 490. The first wiring structure 100 may include a first wiring pattern 130 and a first wiring insulating layer 110. The first wiring structure 100 may include a PCB or a redistribution structure formed through a redistribution process. The flat surfaces of the chip connection bumps 250 and 350 may be electrically connected to the first wiring pattern 130. Subsequently, the carrier substrate 1000 may be removed, and the semiconductor package 11 may be completed.

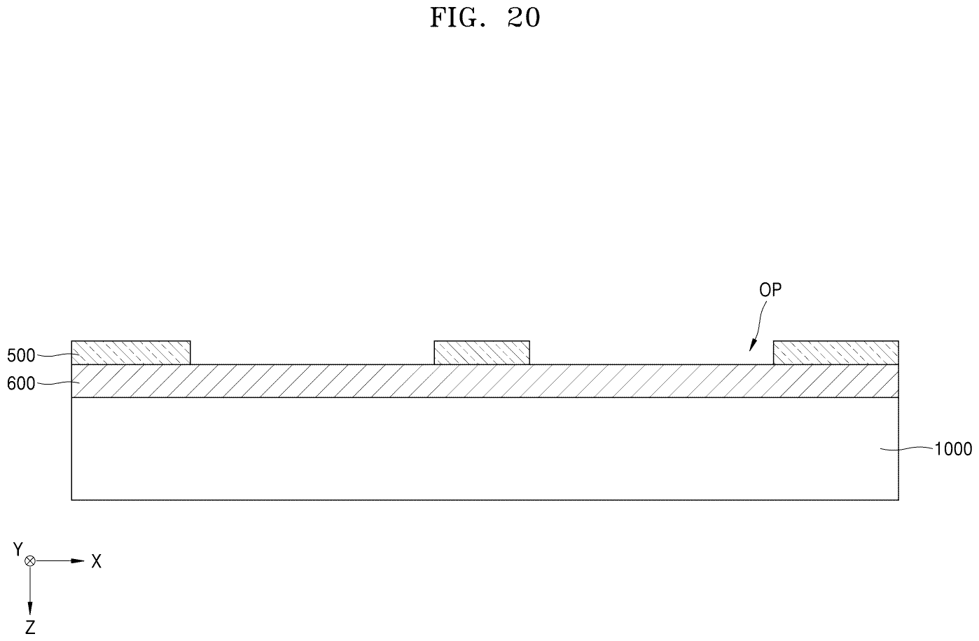

FIGS. 20 to 25 are cross-sectional views illustrating a method of manufacturing the semiconductor package 20 of FIG. 5. Hereinafter, repeated descriptions as those given with reference to FIG. 5 may be omitted, and the description may focus on the differences. Descriptions of directions (e.g., “upper” and “lower”) given below with reference to FIGS. 20 to 25 may be provided to correspond with the orientations of FIGS. 20 to 25.

Referring to FIG. 20, a heat dissipation member 600 may be mounted on a carrier substrate 1000. A molding film 500 may be provided on the upper surface of the heat dissipation member 600. In some embodiments, the molding film 500 may include at least one opening OP. The size of each of the at least one opening OP may be substantially the same as the cross-sectional area of a semiconductor chip to be provided therein. In some embodiments, the molding film 500 in a flat shape without the opening OP may be provided on the heat dissipation member 600. In this case, the semiconductor package 22 of FIG. 7 may be manufactured.

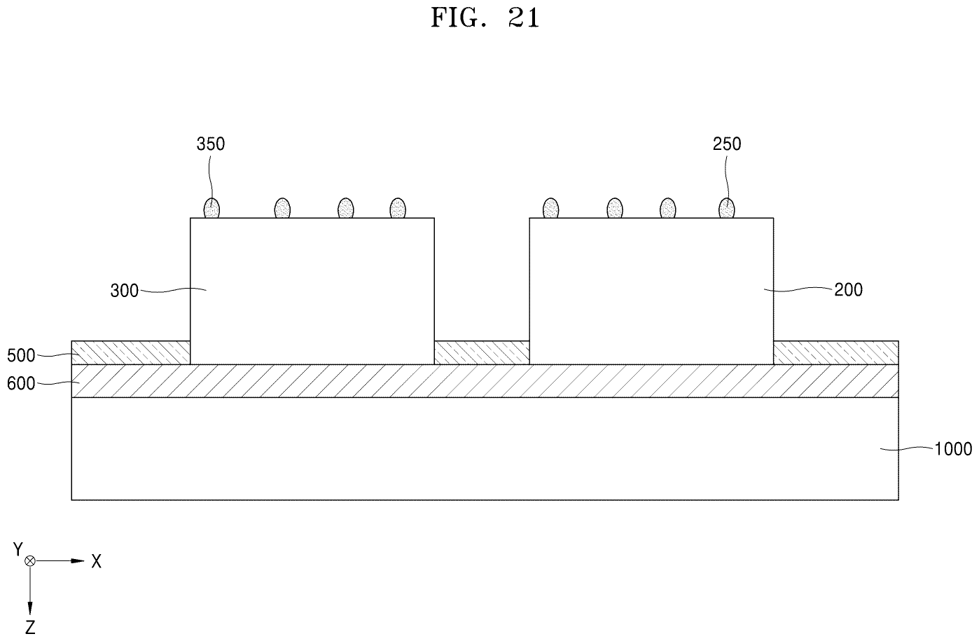

Referring to FIG. 21, a first semiconductor chip 200 and a second semiconductor chip 300 may be mounted so as to fill the at least one opening OP (see FIG. 20) of the molding film 500. Chip connection bumps 250 and 350 may be provided on the upper surface of the first semiconductor chip 200 and the upper surface of the second semiconductor chip 300, respectively.

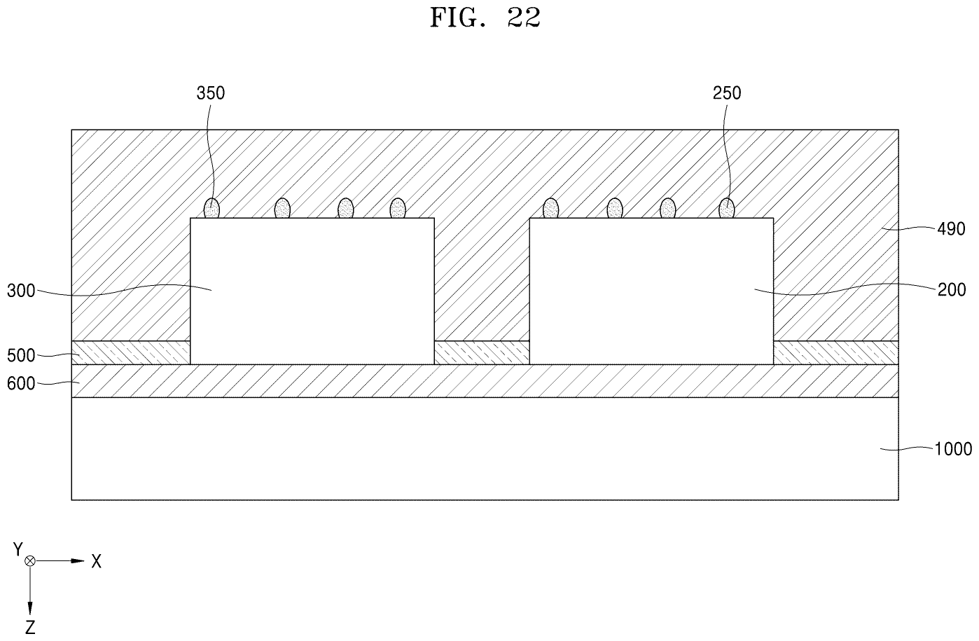

Referring to FIG. 22, a molding member 490 may be formed, which may cover the molding film 500, the first semiconductor chip 200, and the second semiconductor chip 300. The molding member 490 may cover the upper surface of the molding film 500 and the side surfaces and upper surface of each of the first semiconductor chip 200 and the second semiconductor chip 300. The molding member 490 may surround the chip connection bumps 250 and 350.

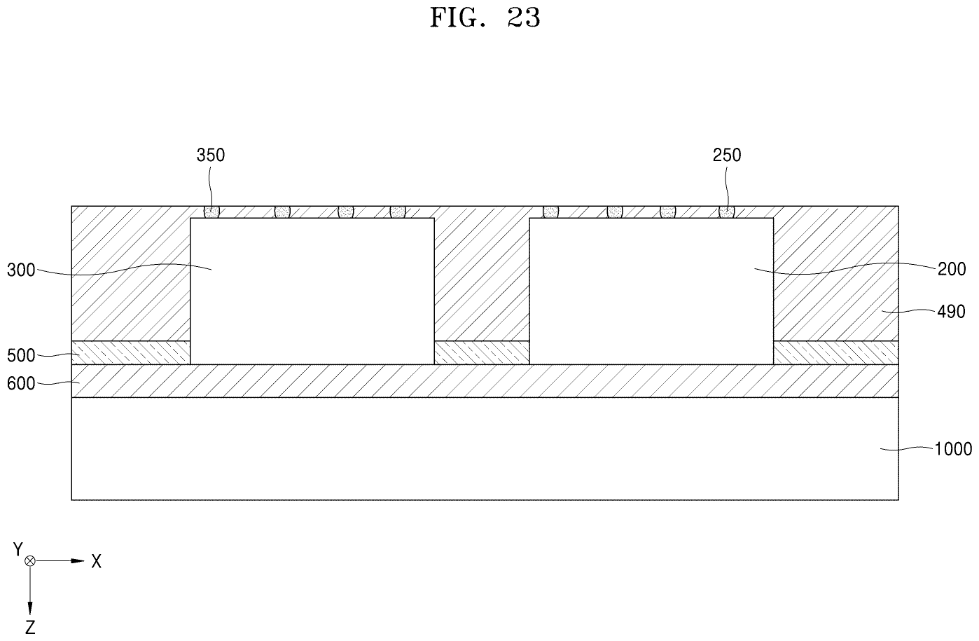

Referring to FIG. 23, the molding member 490 may be etched to at least a certain depth. The molding member 490 may be etched through a CMP process or the like. Etching of the molding member 490 may continue so that the chip connection bumps 250 and 350 are partially etched. Accordingly, the chip connection bumps 250 and 350 may be exposed from the molding member 490 in the vertical direction Z. In this case, the surfaces of the chip connection bumps 250 and 350 that are not in contact with the first semiconductor chip 200 and the second semiconductor chip 300 may be flat.

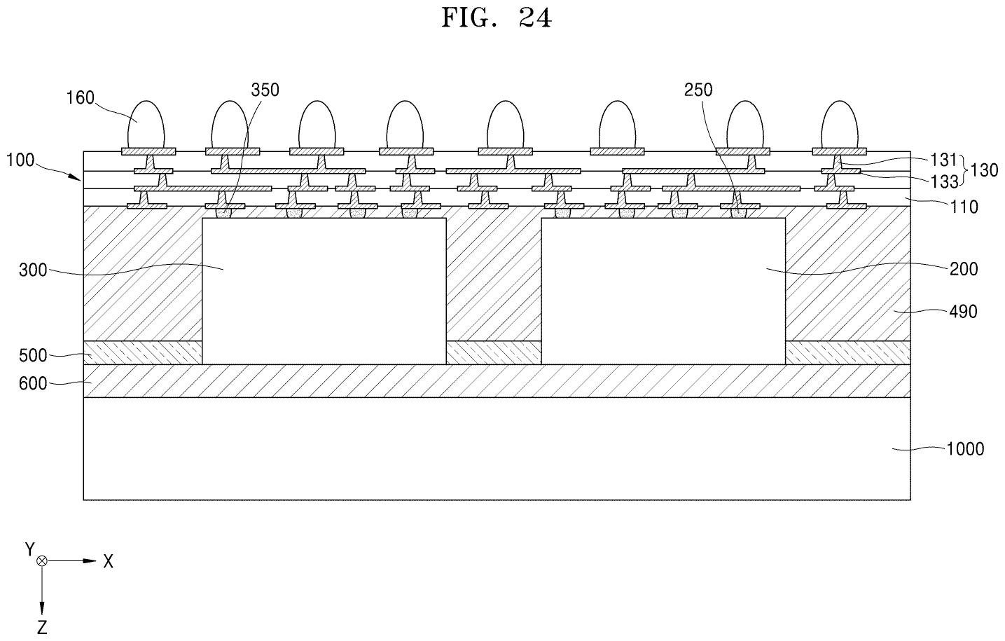

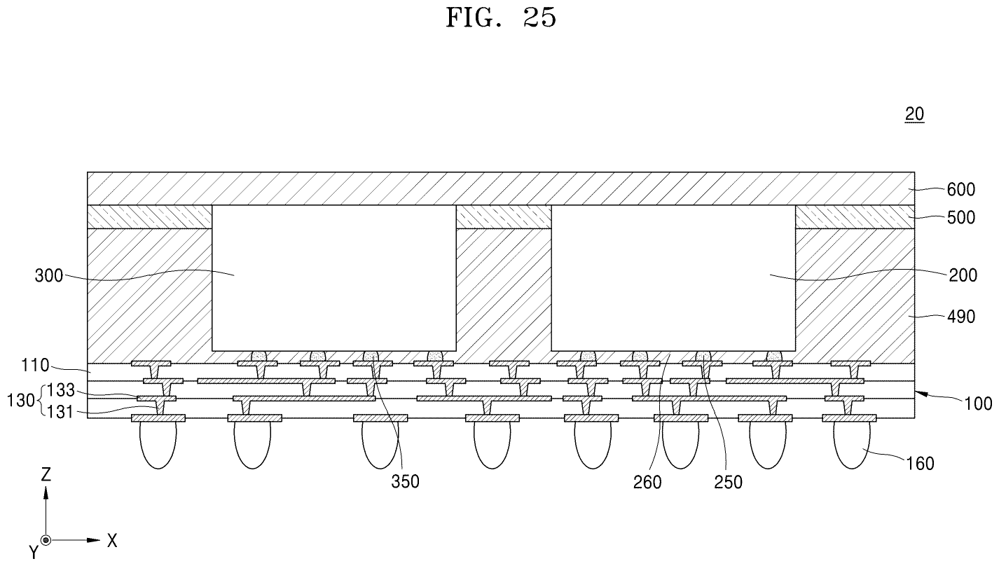

Referring to FIGS. 24 and 25, a first wiring structure 100 may be formed on the molding member 490. The first wiring structure 100 may include a first wiring pattern 130 and a first wiring insulating layer 110. The first wiring structure 100 may include a PCB or a redistribution structure formed through a redistribution process. The flat surfaces of the chip connection bumps 250 and 350 may be electrically connected to the first wiring pattern 130. Subsequently, the carrier substrate 1000 may be removed, and the semiconductor package 20 may be completed.

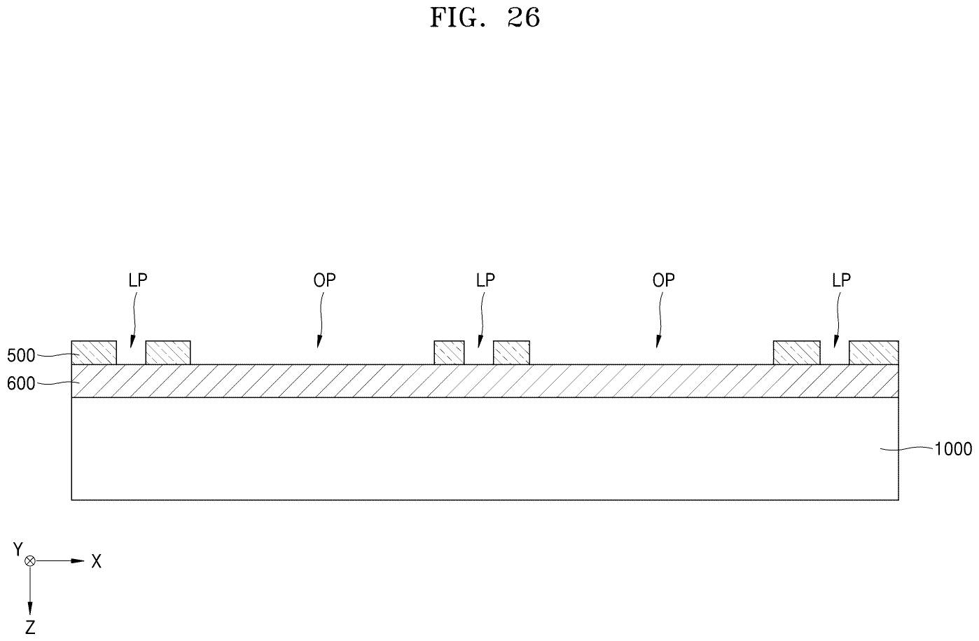

FIGS. 26 to 31 are cross-sectional views illustrating a method of manufacturing the semiconductor package 21 of FIG. 6. Hereinafter, repeated descriptions as those given with reference to FIG. 6 are omitted, and the description may focus on the differences. Descriptions of directions (e.g., “upper” and “lower”) given below with reference to FIGS. 26 to 31 may be provided to correspond with the orientations of FIGS. 26 to 31.

Referring to FIG. 26, a heat dissipation member 600 may be mounted on a carrier substrate 1000. A molding film 500 may be provided on the upper surface of the heat dissipation member 600. In some embodiments, the molding film 500 may include at least one opening OP in which a semiconductor chip is mounted and an opening LP in which a dummy block 480 is mounted. The size of the at least one opening OP may be substantially the same as the cross-sectional area of a semiconductor chip to be provided therein. In addition, the size of the opening LP may be substantially the same as the cross-sectional area of the dummy block 480.

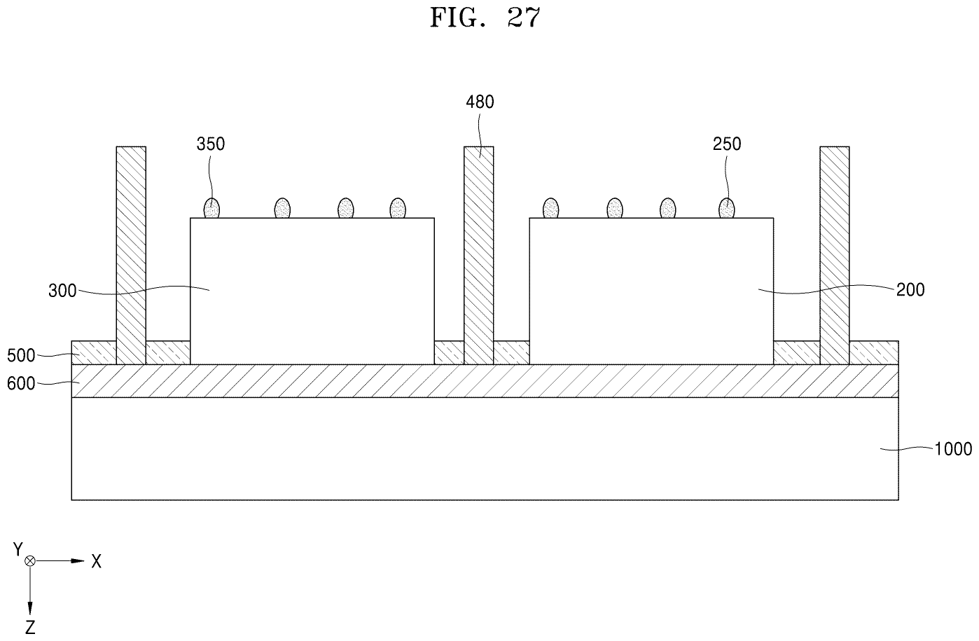

Referring to FIG. 27, a first semiconductor chip 200 and a second semiconductor chip 300 may be mounted so as to fill the at least one opening OP (see FIG. 26) of the molding film 500. Also, the dummy block 480 may be formed so as to fill the opening LP (see FIG. 27). Chip connection bumps 250 and 350 may be provided on the upper surface of the first semiconductor chip 200 and the upper surface of the second semiconductor chip 300, respectively.

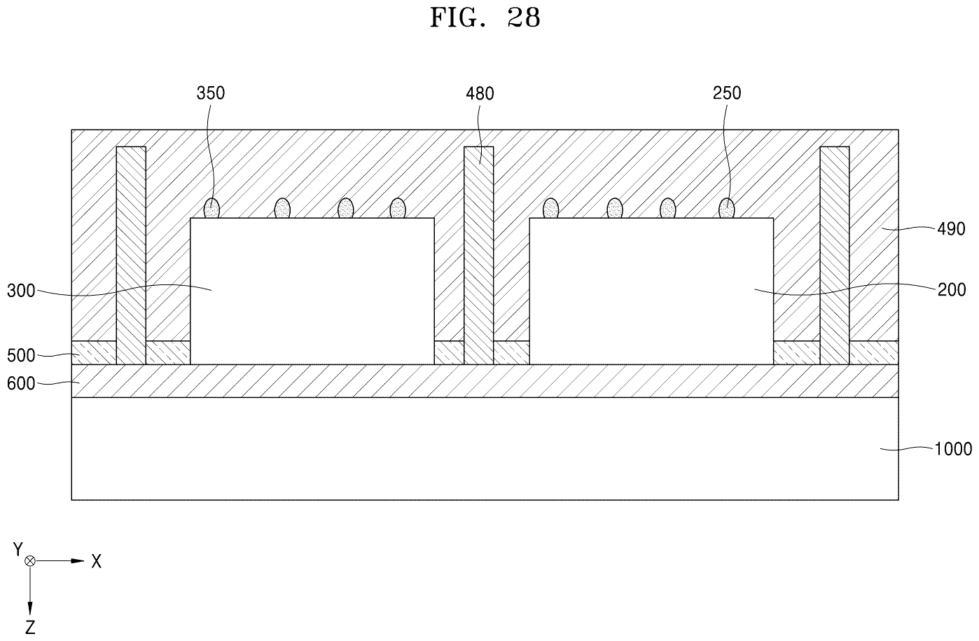

Referring to FIG. 28, a molding member 490 may be formed, which may cover the molding film 500, the dummy block 480, the first semiconductor chip 200, and the second semiconductor chip 300. The molding member 490 may cover the upper surface of the molding film 500, the side surfaces and upper surface of each of the first semiconductor chip 200 and the second semiconductor chip 300, and the side surface and upper surface of the dummy block 480. The molding member 490 may surround the chip connection bumps 250 and 350.

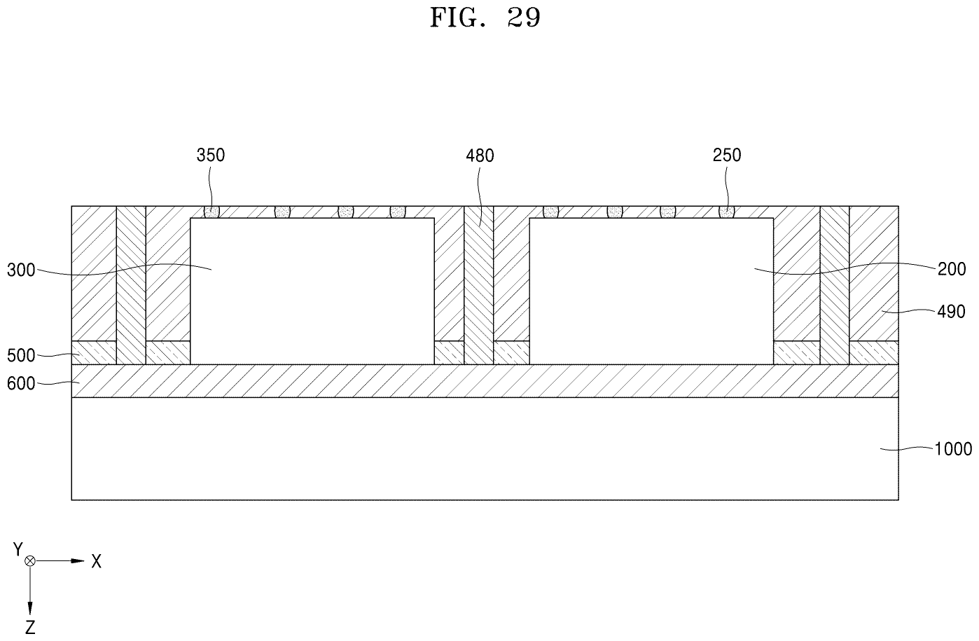

Referring to FIG. 29, the molding member 490 may be etched to at least a certain depth. The molding member 490 may be etched through a CMP process or the like. Etching of the molding member 490 may continue so that the chip connection bumps 250 and 350 are partially etched. Accordingly, the chip connection bumps 250 and 350 may be exposed from the molding member 490 in the vertical direction Z. In this case, the surfaces of the chip connection bumps 250 and 350 that are not in contact with the first semiconductor chip 200 and the second semiconductor chip 300 may be flat. While the molding member 490 is etched, the dummy block 480 may also be partially etched. The upper surfaces of the dummy block 480, the molding member 490, and the chip connection bumps 250 and 350 may be coplanar with each other.

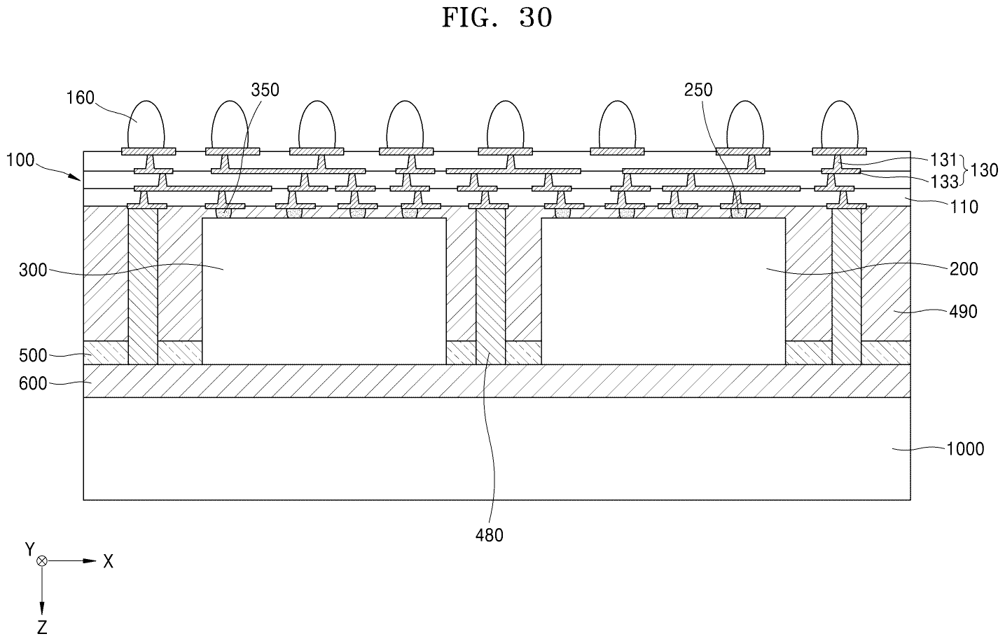

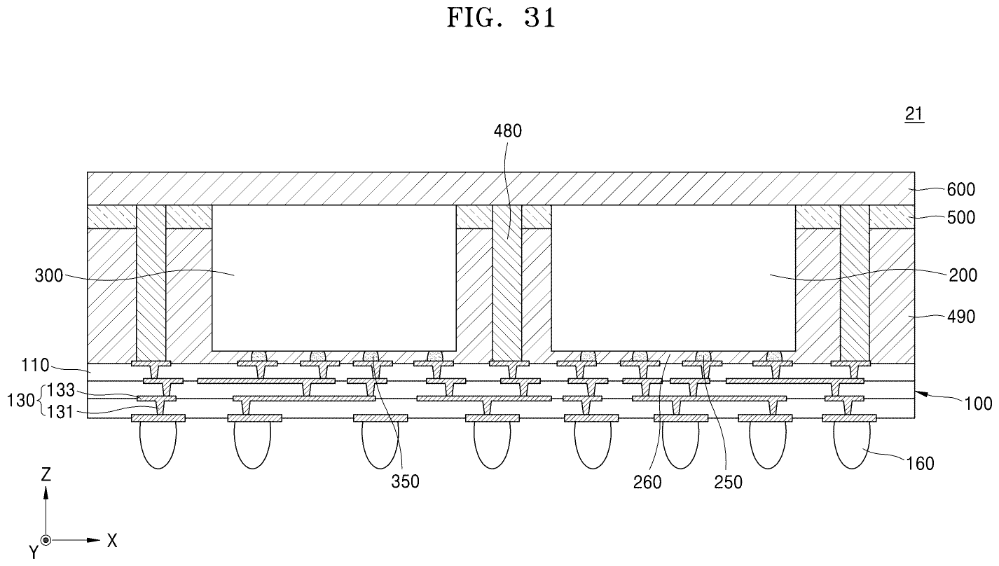

Referring to FIGS. 30 and 31, a first wiring structure 100 may be formed on the molding member 490. The first wiring structure 100 may include a first wiring pattern 130 and a first wiring insulating layer 110. The first wiring structure 100 may include a PCB or a redistribution structure formed through a redistribution process. The flat surfaces of the chip connection bumps 250 and 350 may be electrically connected to the first wiring pattern 130. Subsequently, the carrier substrate 1000 may be removed, and the semiconductor package 21 may be completed.

While non-limiting example embodiments of the present disclosure have been particularly shown and described with reference to the accompanying drawings, it will be understood that various changes in form and details may be made therein without departing from the spirit and scope of the present disclosure.

What is claimed is:

1. A semiconductor package comprising:
a first wiring structure comprising a first wiring pattern and a first wiring insulating layer surrounding the first wiring pattern;
a first semiconductor chip above the first wiring structure;
a second semiconductor chip above the first wiring structure and spaced apart from the first semiconductor chip in a horizontal direction ;
an adhesive layer comprising a first portion on an upper surface of the first semiconductor chip, and further comprising a second portion on an upper surface of the second semiconductor chip;
a molding member on the first wiring structure and surrounding side surfaces of each of the first semiconductor chip, the second semiconductor chip, and the adhesive layer; and
a heat dissipation member on an upper surface of each of the molding member and the adhesive layer.

2. The semiconductor package of claim 1, further comprising a dummy block on the first wiring structure, the dummy block spaced apart from each of the first semiconductor chip and the second semiconductor chip in the horizontal direction.

3. The semiconductor package of claim 2, wherein the dummy block comprises a cylindrical shape extending in a vertical direction.

4. The semiconductor package of claim 2, wherein the dummy block surrounds each of the first semiconductor chip and the second semiconductor chip in the horizontal direction and is spaced apart from each of the first semiconductor chip and the second semiconductor chip in the horizontal direction.

5. The semiconductor package of claim 1, wherein the first wiring insulating layer comprises at least one from among a photo-imageable dielectric (PID) and a photosensitive polyimide (PSPI).

6. The semiconductor package of claim 1, wherein the first wiring insulating layer comprises at least one from among a phenolic resin, an epoxy resin, and a polyimide.

7. The semiconductor package of claim 1, further comprising:
a first chip connection bump on a lower surface of the first semiconductor chip; and
a second chip connection bump on a lower surface of the second semiconductor chip.

8. The semiconductor package of claim 7, wherein the molding member is between the first semiconductor chip and the first wiring structure and between the second semiconductor chip and the first wiring structure, and
wherein the molding member surrounds the first chip connection bump and the second chip connection bump.

9. The semiconductor package of claim 7, wherein a surface of the first chip connection bump is flat, and
wherein a surface of the second chip connection bump is flat.

10. The semiconductor package of claim 1, wherein the adhesive layer comprises a die attach film, and a thermal conductivity of the adhesive layer is greater than a thermal conductivity of the molding member.

11. The semiconductor package of claim 1, wherein a footprint of the first portion of the adhesive layer is the same as a footprint of the first semiconductor chip, and a footprint of the second portion of the adhesive layer is the same as a footprint of the second semiconductor chip.

12. A semiconductor package comprising:
a first wiring structure comprising a first wiring pattern and a first wiring insulating layer surrounding the first wiring pattern;
a first semiconductor chip above the first wiring structure;
a second semiconductor chip above the first wiring structure and spaced apart from the first semiconductor chip in a horizontal direction;
a heat dissipation member above the first semiconductor chip and the second semiconductor chip;
a molding film bonding the heat dissipation member to the first semiconductor chip and the second semiconductor chip; and
a molding member on the first wiring structure and surrounding side surfaces of each of the first semiconductor chip and the second semiconductor chip,
wherein a thermal conductivity of the molding film is greater than a thermal conductivity of the molding member.

13. The semiconductor package of claim 12, further comprising:
a first chip connection bump on a lower surface of the first semiconductor chip; and
a second chip connection bump on a lower surface of the second semiconductor chip.

14. The semiconductor package of claim 13, wherein the molding member is between the first semiconductor chip and the first wiring structure and between the second semiconductor chip and the first wiring structure, and
wherein the molding member surrounds the first chip connection bump and the second chip connection bump.

15. The semiconductor package of claim 12, further comprising a dummy block on the first wiring structure, the dummy block spaced apart from each of the first semiconductor chip and the second semiconductor chip in the horizontal direction.

16. The semiconductor package of claim 15, wherein a cross-section of the dummy block on a plane that includes the horizontal direction has a quadrangular ring shape.

17. The semiconductor package of claim 12, wherein the molding film is between the heat dissipation member and the molding member, between the heat dissipation member and the first semiconductor chip, and between the heat dissipation member and the second semiconductor chip.

18. A semiconductor package comprising:
a first wiring structure comprising a first wire and a first wiring insulating layer surrounding the first wire;
a first semiconductor chip above the first wiring structure and connected to the first wiring structure via a first chip connection bump;
a second semiconductor chip above the first wiring structure and connected to the first wiring structure via a second chip connection bump, the second semiconductor chip spaced apart from the first semiconductor chip in a horizontal direction;
a dummy block on the first wiring structure and spaced apart from each of the first semiconductor chip and the second semiconductor chip in the horizontal direction;
an adhesive layer comprising a first portion on an upper surface of the first semiconductor chip, and further comprising a second portion on an upper surface of the second semiconductor chip;
a molding member on the first wiring structure and surrounding side surfaces of each of the first semiconductor chip, the second semiconductor chip, the dummy block, and the adhesive layer; and
a heat dissipation member on an upper surface of each of the molding member, the dummy block, and the adhesive layer,
wherein the molding member is between the first semiconductor chip and the first wiring structure and between the second semiconductor chip and the first wiring structure, and the molding member surrounds the first chip connection bump and the second chip connection bump,
wherein a surface of the first chip connection bump, that faces away from the first semiconductor chip, and a surface the second chip connection bump, that faces away from the second semiconductor chip, are flat, and
wherein the upper surface of the adhesive layer is coplanar with the upper surface of the molding member.

19. The semiconductor package of claim 18, wherein the dummy block comprises a cylindrical shape extending in a vertical direction.

20. The semiconductor package of claim 18, wherein the dummy block surrounds each of the first semiconductor chip and the second semiconductor chip in the horizontal direction and is spaced apart from each of the first semiconductor chip and the second semiconductor chip in the horizontal direction.
